(19) United States
(12) Patent Application Publication
(10) Pub. No.: US 2026/0026218 A1
(43) Pub. Date: Jan. 22, 2026

(54) DISPLAY DEVICE AND ELECTRONIC DEVICE INCLUDING THE SAME

(71) Applicant: Samsung Display Co., LTD., Yongin-si (KR)

(72) Inventors: CHANGHO YI, Yongin-si (KR); DAWOON JUNG, Yongin-si (KR); YU-GWANG JEONG, Yongin-si (KR)

(21) Appl. No.: 19/085,827

(22) Filed: Mar. 20, 2025

(30) Foreign Application Priority Data
Jul. 17, 2024 (KR) 10-2024-0094685
Oct. 14, 2024 (KR) 10-2024-0139537

(51) Int. Cl. H10K 59/131; H10K 59/12; H10K 59/124

(52) U.S. Cl. CPC H10K 59/131; H10K 59/1201; H10K 59/124

(57) ABSTRACT

A display device includes a first transistor, an insulating layer disposed on the first transistor, a first connecting electrode disposed on the insulating layer and connected to the first transistor through a contact hole defined in the insulating layer, and a light emitting element including an anode disposed on the first connecting electrode and electrically connected to the first connecting electrode. The first connecting electrode includes a first electrode disposed on a portion of the insulating layer adjacent to the contact hole, and a second electrode disposed on the first electrode and within the contact hole and connected to the first transistor, and an upper surface of a portion of the first electrode adjacent to the contact hole has an inclined surface.

This application claims priority to Korean Patent Application No. 10-2024-0094685, filed on Jul. 17, 2024, and Korean Patent Application No. 10-2024-0139537, filed on Oct. 14, 2024, and all the benefits accruing therefrom under 35 U.S.C. § 119, the contents of which in their entirety are herein incorporated by reference.

### BACKGROUND

Embodiments of the present disclosure described herein relate to a display device and an electronic device including the same.

In general, electronic devices, such as smart phones, digital cameras, notebook computers, car navigation devices, smart televisions, and the like, which provide an image to a user include a display device for displaying an image. The display device generates an image and provides the generated image to the user through a display screen.

The display device includes a display panel including a plurality of pixels for generating an image, a scan driver that applies scan signals to the pixels, and a data driver that applies data voltages to the pixels. The pixels receive the data voltages in response to the scan signals and generate an image using the data voltages.

Each of the pixels includes a light emitting element and a plurality of transistors connected to the light emitting element. The light emitting element is driven by the transistors to generate light. Among the transistors, a drive transistor is connected to the light emitting element through a connecting electrode. The connecting electrode is connected to the drive transistor through a contact hole defined in an insulating layer. The area occupied by the contact hole in each of the pixels is limited, and therefore a technology for precisely manufacturing the contact hole is desirable.

### SUMMARY

Embodiments of the present disclosure provide a display device having a structure for precisely manufacturing a contact hole for arranging a first connecting electrode connecting a first transistor to a light emitting element and a method for manufacturing the display device.

According to an embodiment, a display device includes a first transistor, an insulating layer disposed on the first transistor, a first connecting electrode disposed on the insulating layer and connected to the first transistor through a contact hole defined in the insulating layer, and a light emitting element including an anode disposed on the first connecting electrode and electrically connected to the first connecting electrode. The first connecting electrode includes a first electrode disposed on a portion of the insulating layer adjacent to the contact hole and a second electrode disposed on the first electrode and within the contact hole and connected to the first transistor, and an upper surface of a portion of the first electrode adjacent to the contact hole has an inclined surface.

According to an embodiment, a method for manufacturing a display device includes: providing a first transistor on a substrate, providing an insulating layer on the first transistor, providing a first electrode on the insulating layer, removing a first portion of the first electrode that overlaps a hole area of the insulating layer, defining a contact hole in the insulating layer by removing the hole area using a remaining portion of the first electrode as a mask, providing a second electrode on the first electrode and within the contact hole, removing portions of the first electrode and the second electrode other than a first portion of the second electrode disposed within the contact hole and second portions of the first electrode and the second electrode disposed on a portion of the insulating layer adjacent to the contact hole, providing a light emitting element on a first connecting electrode including the first portion of the second electrode and the second portions of the first electrode and the second electrode, and electrically connecting the first connecting electrode to an anode of the light emitting element.

According to an embodiment, an electronic device includes a camera module and a display device that displays an image corresponding to a photographed image obtained through the camera module. The display device includes a first transistor, an insulating layer disposed on the first transistor, a first connecting electrode disposed on the insulating layer and connected to the first transistor through a contact hole defined in the insulating layer, and a light emitting element including an anode disposed on the first connecting electrode and electrically connected to the first connecting electrode. The first connecting electrode includes a first electrode disposed on a portion of the insulating layer adjacent to the contact hole and a second electrode disposed on the first electrode and within the contact hole and connected to the first transistor, and an upper surface of a portion of the first electrode adjacent to the contact hole has an inclined surface.

### BRIEF DESCRIPTION OF THE FIGURES

The above and other aspects and features of the present disclosure will become apparent by describing in detail embodiments thereof with reference to the accompanying drawings.

FIG. 1 is a perspective view of a display device according to an embodiment of the present disclosure.

FIG. 2 is a view illustrating a cross-section of the display device illustrated in FIG. 1.

FIG. 3 is a view illustrating a cross-section of a display panel illustrated in FIG. 2

FIG. 4 is a plan view of the display panel illustrated in FIG. 2.

FIG. 5 is a view illustrating a display device according to an embodiment of the present disclosure.

FIG. 6 is an exploded perspective view of the display device illustrated in FIG. 5.

FIG. 7 is a view illustrating an equivalent circuit of one of pixels illustrated in FIG. 4.

FIG. 8 is a timing chart of signals for operating the pixel illustrated in FIG. 7.

FIG. 9 is a schematic sectional view illustrating a light emitting element, a first transistor, and a second transistor of the pixel illustrated in FIG. 7.

FIG. 10 is an enlarged sectional view of a first connecting electrode, a semiconductor layer connected to the first connecting electrode, and the second transistor illustrated in FIG. 9.

FIG. 11 is an enlarged view of a first area AA1 illustrated in FIG. 10.

FIG. 12 is a view illustrating a cross-sectional configuration of a first connecting electrode and a second gate electrode according to an embodiment of the present disclosure.

FIGS. 13A to 13G are views for explaining a method of manufacturing the display device including the first connecting electrode illustrated in FIG. 10.

FIGS. 14A to 14C are views for explaining a method of manufacturing the display device including the first connecting electrode illustrated in FIG. 12.

FIG. 15 is a view illustrating a first contact hole formed by an etching process when a first electrode is not used in FIG. 13C.

FIGS. 16A and 16B are views illustrating a fence structure depending on a polymer layer disposed on an inner surface of a photoresist layer.

FIG. 17 is a view illustrating a configuration in which the first electrode of the first connecting electrode described above is used in the fence structure illustrated in FIG. 16B.

FIG. 18 is a view for explaining a hydrogen implantation process for a second semiconductor layer of the second transistor illustrated in FIG. 10.

FIG. 19 is a block diagram of an electronic device including the display device according to an embodiment of the present disclosure.

### DETAILED DESCRIPTION

In this specification, when a component (or, an area, a layer, a part, etc.) is referred to as being “on”, “connected to” or “coupled to” another component, this means that the component may be directly on, connected to, or coupled to the other component or a third component may be present therebetween.

Identical reference numerals refer to identical components. Additionally, in the drawings, the thicknesses, proportions, and dimensions of components are exaggerated for effective description.

As used herein, the term “and/or” includes all of one or more combinations defined by related components.

Terms such as “first”, “second”, “first-first”, “second-first” and the like may be used to describe various components, but the components should not be limited by the terms. The terms may be used only for distinguishing one component from other components. For example, without departing the scope of the present disclosure, a first component may be referred to as a second component, and similarly, the second component may also be referred to as the first component. The terms of a singular form may include plural forms unless otherwise specified.

In addition, terms such as “below”, “under”, “above”, and “over” are used to describe a relationship between components illustrated in the drawings. The terms are relative concepts and are described based on directions illustrated in the drawing.

Unless otherwise defined, all terms used herein, including technical or scientific terms, have the same meanings as those generally understood by those skilled in the art to which the present disclosure pertains. Such terms as those defined in a generally used dictionary are to be interpreted as having meanings equal to the contextual meanings in the relevant field of art, and are not to be interpreted as having ideal or excessively formal meanings unless clearly defined as having such in the present application.

It should be understood that terms such as “comprise”, “include”, and “have”, when used herein, specify the presence of stated features, numbers, steps, operations, components, parts, or combinations thereof, but do not preclude the presence or addition of one or more other features, numbers, steps, operations, components, parts, or combinations thereof.

Throughout the disclosure, the expression “at least one of a, b or c” indicates only a, only b, only c, both a and b, both a and c, both b and c, all of a, b, and c, or variations thereof. Hereinafter, embodiments of the present disclosure will be described with reference to the accompanying drawings.

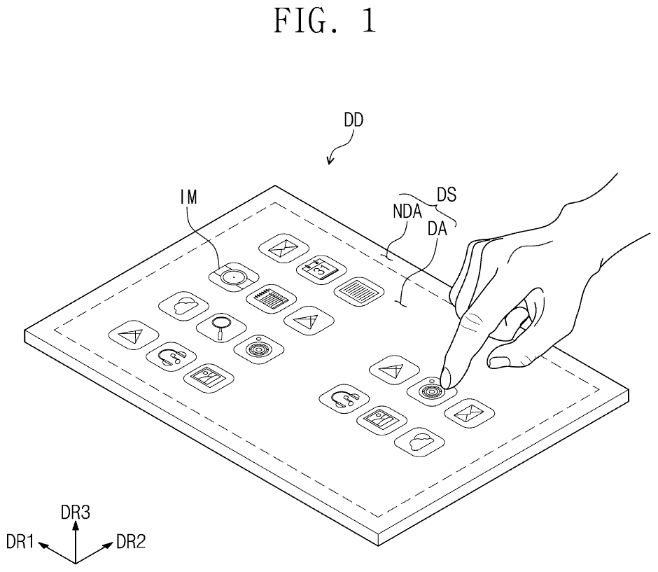

FIG. 1 is a perspective view of a display device according to an embodiment of the present disclosure.

Referring to FIG. 1, the display device DD according to an embodiment of the present disclosure may have a rectangular shape with long sides extending in a first direction DR1 and short sides extending in a second direction DR2 crossing the first direction DR1. However, without being limited thereto, the display device DD may have various shapes such as a circular shape, a polygonal shape, and the like. Hereinafter, a direction substantially perpendicular to a plane defined by the first direction DR1 and the second direction DR2 is defined as a third direction DR3. As used herein, the expression “when viewed from above the plane” may mean that it is viewed in the third direction DR3 (i.e., plan view).

The upper surface of the display device DD may be defined as a display surface DS and may have the plane defined by the first direction DR1 and the second direction DR2. Images IM generated by the display device DD may be provided to a user through the display surface DS.

The display surface DS may include a display area DA and a non-display area NDA around the display area DA. The display area DA may display an image, and the non-display area NDA may not display an image. The non-display area NDA may surround the display area DA and may define the border of the display device DD that is printed in a certain color.

The display device DD may be used in large electronic devices such as a television, a monitor, and a billboard. In addition, the display device DD may be used in small and medium-sized electronic devices such as a personal computer, a notebook computer, a personal digital terminal, a car navigation device, a game machine, a smart phone, a tablet computer, and a camera. However, these electronic devices are merely illustrative, and the display device DD may be used in other electronic devices without departing from the spirit and scope of the present disclosure.

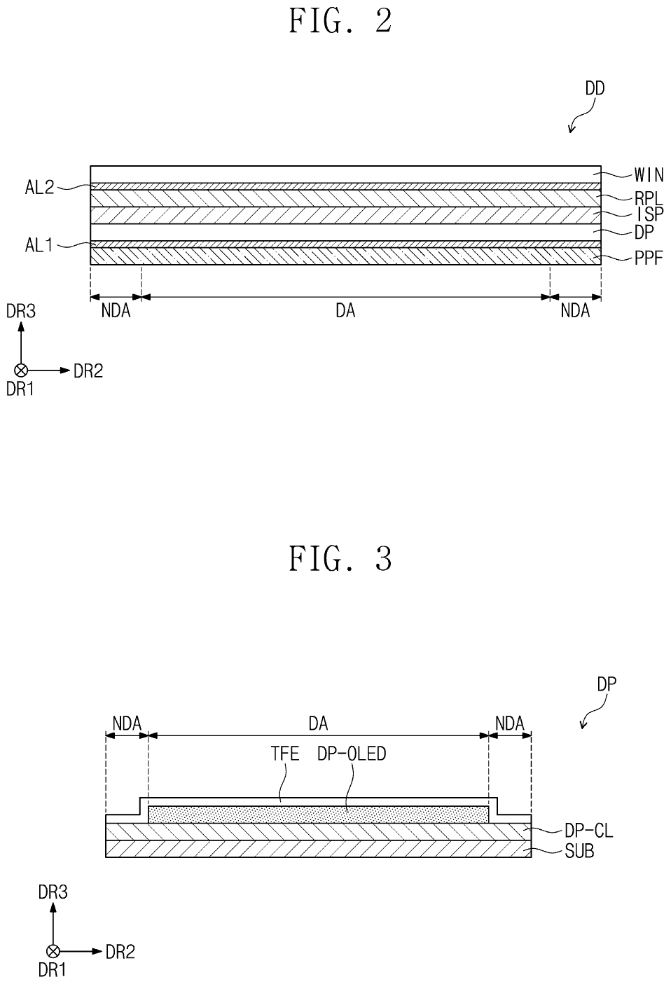

FIG. 2 is a view illustrating a cross-section of the display device illustrated in FIG. 1.

For example, in FIG. 2, a cross-section of the display device DD viewed in the first direction DR1 is illustrated.

Referring to FIG. 2, the display device DD may include a display panel DP, an input sensing part ISP, an anti-reflective layer RPL, a window WIN, a panel protection film PPF, a first adhesive layer AL1, and a second adhesive layer AL2.

The display panel DP may be a flexible display panel. The display panel DP according to an embodiment of the present disclosure may be an emissive display panel. For example, the display panel DP may be an organic light emitting display panel or an inorganic light emitting display panel. An emissive layer of the organic light emitting display panel may include an organic luminescent material. An emissive layer of the inorganic light emitting display panel may include quantum dots and quantum rods. Hereinafter, the display panel DP will be described as an organic light emitting display panel.

The input sensing part ISP may be disposed on the display panel DP. The input sensing part ISP may include a plurality of sensing parts (not illustrated) for sensing an external input in a capacitance type. The input sensing part ISP may be directly manufactured on the display panel DP when the display device DD is manufactured. However, without being limited thereto, the input sensing part ISP may be manufactured as a panel separate from the display panel DP and may be attached to the display panel DP by an adhesive layer.

The anti-reflective layer RPL may be disposed on the input sensing part ISP. The anti-reflective layer RPL may be directly manufactured on the input sensing part ISP when the display device DD is manufactured. However, without being limited thereto, the anti-reflective layer RPL may be manufactured as a separate panel and may be attached to the input sensing part ISP by an adhesive layer.

The anti-reflective layer RPL may be defined as a film for preventing reflection of external light. The anti-reflective layer RPL may decrease the reflectance of external light incident toward the display panel DP from above the display device DD. The external light may not be visible to the user due to the anti-reflective layer RPL.

When external light travelling toward the display panel DP is reflected from the display panel DP and provided back to the user, the user may visually recognize the external light as in a mirror. To prevent such a phenomenon, for example, the anti-reflective layer RPL may include a plurality of color filters that display the same colors as those of pixels of the display panel DP.

The color filters may filter external light into the same colors as those of the pixels. In this case, the external light may not be visible to the user. However, without being limited thereto, the anti-reflective layer RPL may include a phase retarder and/or a polarizer to decrease the reflectance of the external light.

The window WIN may be disposed on the anti-reflective layer RPL. The window WIN may protect the display panel DP, the input sensing part ISP, and the anti-reflective layer RPL from external scratches and impacts.

The panel protection film PPF may be disposed under the display panel DP. The panel protection film PPF may protect the bottom of the display panel DP. The panel protection film PPF may include a flexible plastic material such as polyethylene terephthalate (“PET”).

The first adhesive layer AL1 may be disposed between the display panel DP and the panel protection film PPF, and the display panel DP and the panel protection film PPF may be bonded to each other by the first adhesive layer AL1. The second adhesive layer AL2 may be disposed between the window WIN and the anti-reflective layer RPL, and the window WIN and the anti-reflective layer RPL may be bonded to each other by the second adhesive layer AL2.

FIG. 3 is a view illustrating a cross-section of the display panel illustrated in FIG. 2.

For example, in FIG. 3, a cross-section of the display panel DP viewed in the first direction DR1 is illustrated.

Referring to FIG. 3, the display panel DP may include a substrate SUB, a circuit element layer DP-CL disposed on the substrate SUB, a display element layer DP-OLED disposed on the circuit element layer DP-CL, and a thin film encapsulation layer TFE disposed on the display element layer DP-OLED.

The substrate SUB may include a display area DA and a non-display area NDA around the display area DA. The substrate SUB may include a flexible plastic material such as glass or polyimide (“PI”). The display element layer DP-OLED may be disposed on the display area DA.

A plurality of pixels may be disposed in the circuit element layer DP-CL and the display element layer DP-OLED. Each of the pixels may include a transistor disposed in the circuit element layer DP-CL and a light emitting element disposed in the display element layer DP-OLED and connected to the transistor.

The thin film encapsulation layer TFE may be disposed on the circuit element layer DP-CL to cover the display element layer DP-OLED. The thin film encapsulation layer TFE may protect the pixels from moisture, oxygen, and external foreign matter.

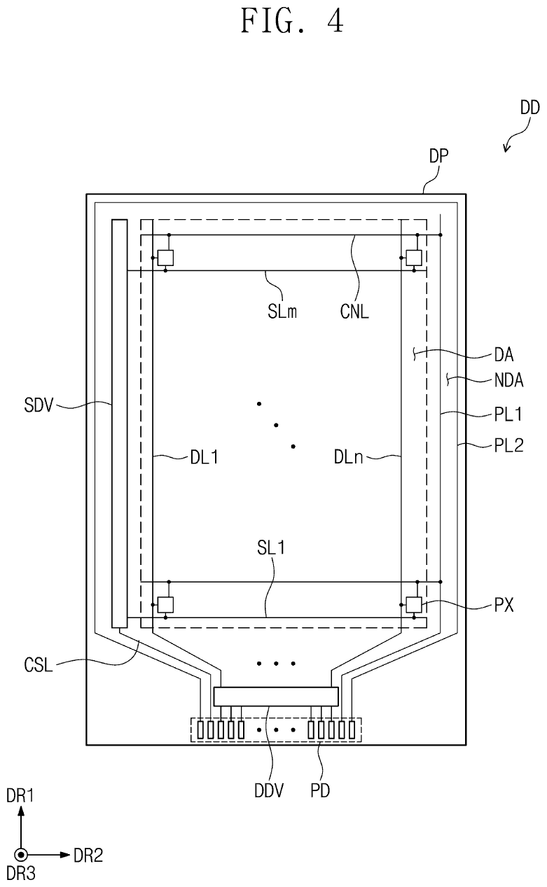

FIG. 4 is a plan view of the display panel illustrated in FIG. 2.

Referring to FIG. 4, the display device DD may include the display panel DP, a scan driver SDV, a data driver DDV, and a plurality of pads PD.

The display panel DP may have a rectangular shape with long sides extending in the first direction DR1 and short sides extending in the second direction DR2. However, the shape of the display panel DP is not limited thereto. The display panel DP may include a display area DA and a non-display area NDA surrounding the display area DA.

The display panel DP may include a plurality of pixels PX, a plurality of scan lines SL1 to SLm, a plurality of data lines DL1 to DLn, a control line CSL, a first power line PL1, a second power line PL2, and connecting lines CNL. “m” and “n” are natural numbers.

The pixels PX may be disposed in the display area DA. The pixels PX may be arranged in a matrix form. However, an arrangement of the pixels PX is not limited thereto.

The scan driver SDV may be disposed in the non-display area NDA adjacent to one of the long sides of the display panel DP. The scan driver SDV may be adjacent to the left side of the display panel DP when viewed from above the plane.

The data driver DDV may be disposed in the non-display area NDA adjacent to one of the short sides of the display panel DP. The data driver DDV may be adjacent to the lower end of the display panel DP when viewed from above the plane.

The scan lines SL1 to SLm may extend in the second direction DR2 and may be connected to the pixels PX and the scan driver SDV. The data lines DL1 to DLn may extend in the first direction DR1 and may be connected to the pixels PX and the data driver DDV.

The first power line PL1 may extend in the first direction DR1 and may be disposed in the non-display area NDA. The first power line PL1 may be adjacent to the long side of the display panel DP where the scan driver SDV is not disposed.

The connecting lines CNL may extend in the second direction DR2 and may be arranged in the first direction DR1. The connecting lines CNL may be connected to the first power line PL1 and the pixels PX. A first voltage may be applied to the pixels PX through the first power line PL1 and the connecting lines CNL connected with each other.

The second power line PL2 may be disposed in the non-display area NDA and may extend along the long sides of the display panel DP and the other short side of the display panel DP where the data driver DDV is not disposed. The second power line PL2 may be disposed outward of the scan driver SDV.

Although not illustrated, the second power line PL2 may extend toward the display area DA and may be connected to the pixels PX. A second voltage may be applied to the pixels PX through the second power line PL2.

The control line CSL may be connected to the scan driver SDV and may extend toward the lower end of the display panel DP. A control signal for controlling an operation of the scan driver SDV may be provided to the scan driver SDV through the control line CSL.

The pads PD may be disposed in the non-display area NDA adjacent to the lower end of the display panel DP and may be closer to the lower end of the display panel DP than the data driver DDV. The data driver DDV, the first power line PL1, the second power line PL2, and the control line CSL may be connected to the pads PD. The data lines DL1 to DLn may be connected to the data driver DDV, and the data driver DDV may be connected to the pads PD corresponding to the data lines DL1 to DLn.

Although not illustrated, the display device DD may further include a timing controller for controlling operations of the scan driver SDV and the data driver DDV and a voltage generator for generating the first voltage and the second voltage. The timing controller and the voltage generator may be mounted on a printed circuit board and may be connected to the pads PD through the printed circuit board.

The scan driver SDV may generate a plurality of scan signals, and the scan signals may be applied to the pixels PX through the scan lines SL1 to SLm. The data driver DDV may generate a plurality of data voltages, and the data voltages may be applied to the pixels PX through the data lines DL1 to DLn.

The pixels PX may receive the data voltages in response to the scan signals. The pixels PX may display an image by emitting light having luminance corresponding to the data voltages.

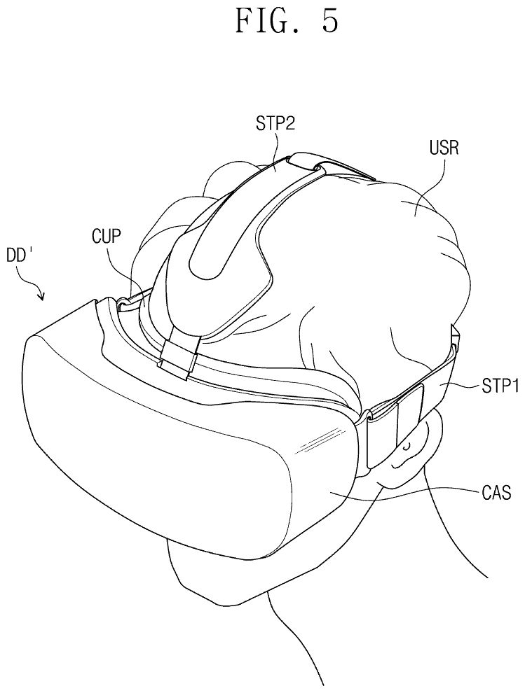

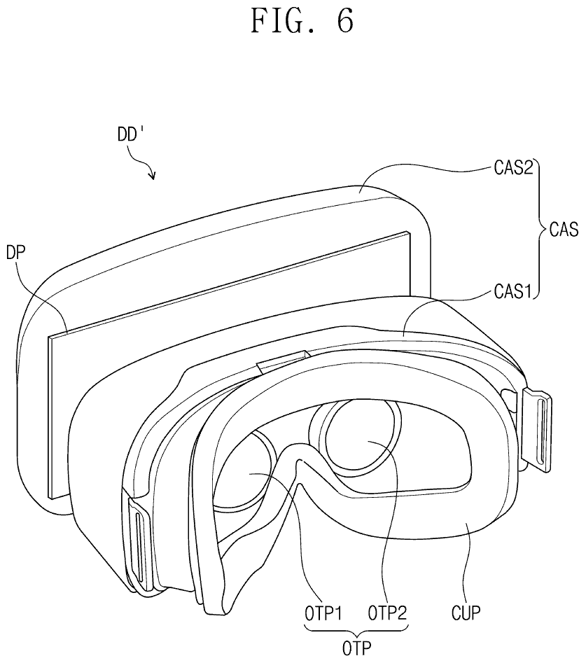

FIG. 5 is a view illustrating a display device according to an embodiment of the present disclosure.

Referring to FIG. 5, the display device DD′ according to an embodiment of the present disclosure may be defined as a head-mounted display device. The display device DD′ may be worn on the head of a user USR.

The display device DD′ may block a peripheral view of the user USR and may provide an image to the user USR. The display device DD′ may provide virtual reality to the user USR.

The display device DD′ may include a case CAS, a cushion CUP, and straps STP1 and STP2. The case CAS may be worn on the user USR. A display panel DP that displays an image and an acceleration sensor (not illustrated) may be accommodated inside the case CAS. The display panel DP may be the display panel DP illustrated in FIG. 4.

The acceleration sensor may sense a movement of the user USR and may transfer a certain signal to the display panels DP. Accordingly, the display panels DP may provide an image corresponding to a change in the gaze of the user USR. Thus, the user USR may experience virtual reality similar to actual reality.

The cushion CUP may be disposed between the case CAS and the user USR. The cushion CUP may include a material that is free to deform. For example, the cushion CUP may include a polymer resin (e.g., polyurethane, polycarbonate, polypropylene, or polyethylene). Alternatively, the cushion CUP may include a sponge formed by causing liquid rubber, a urethane-based material, or an acrylic material to foam.

The cushion CUP may bring the case CAS into close contact with the user USR to improve the wearing comfort of the user USR. The cushion CUP may be detachable from the case CAS.

The straps STP1 and STP2 may be coupled with the case CAS to enable the case CAS to be easily worn on the user USR. The straps STP1 and STP2 may include the first strap STP1 and the second strap STP2.

The first strap STP1 may be worn along the circumference of the head of the user USR. The first strap STP1 may fix the case CAS to the user USR to bring the case CAS into close contact with the head of the user USR.

The second strap STP2 may connect the case CAS and the first strap STP1 along the upper part of the head of the user USR. The second strap STP2 may prevent the case CAS from slipping down.

FIG. 6 is an exploded perspective view of the display device illustrated in FIG. 5.

Referring to FIG. 6, the case CAS may include a first case CAS1 and a second case CAS2. The first case CAS1 and the second case CAS2 may be separated from each other.

The display panel DP may be disposed between the first case CAS1 and the second case CAS2. The first case CAS1 and the second case CAS2 may be coupled with each other, and accordingly the display panel DP may be accommodated in the case CAS. For example, the display panel DP may provide a left-eye image and a right-eye image to the user USR. Accordingly, the display panel DP may provide a stereoscopic image to the user USR.

An optical system OTP may be disposed inside the first case CAS1. The optical system OTP may magnify an image provided from the display panels DP. The optical system OTP may be disposed between the display panels DP and the eyes of the user USR. The optical system OTP may include a left-eye optical system OTP1 and a right-eye optical system OTP2. The left-eye optical system OTP1 may magnify and provide the image to the left pupil of the user USR, and the right-eye optical system OTP2 may magnify and provide the image to the right pupil of the user USR.

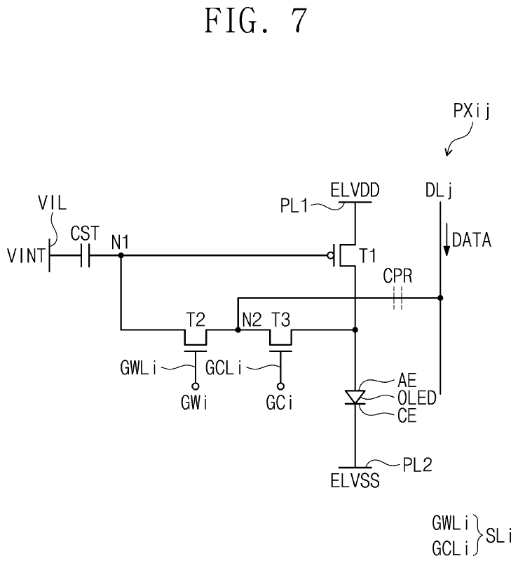

FIG. 7 is a view illustrating an equivalent circuit of one of the pixels illustrated in FIG. 4.

For example, in FIG. 7, a pixel PXij connected to the i^{th} scan line SLi and the j^{th} data line DLj is illustrated. “i” and “j” are natural numbers. Hereinafter, for convenience of description, the ordinal numbers i^{th} and j^{th} will be omitted.

Referring to FIG. 7, the pixel PXij may include a first transistor T1, a second transistor T2, a third transistor T3, a light emitting element OLED, and a capacitor CST.

The scan line SLi may include a write scan line GWLi and a compensation scan line GCLi. The write scan line GWLi may receive a write scan signal GWi, and the compensation scan line GCLi may receive a compensation scan signal GCi.

A parasitic capacitor CPR may be unintentionally formed between a second node N2 between the second transistor T2 and the third transistor T3 and the data line DLj. However, the parasitic capacitor CPR is not a component of the pixel PXij, and therefore description of the parasitic capacitor CPR will be omitted in the description of an operation of the pixel PXij.

The light emitting element OLED may be defined as an organic light emitting element. The light emitting element OLED may include an anode AE and a cathode CE. The anode AE may be connected to the first power line PL1 through the first transistor T1. The cathode CE may be connected to the second power line PL2. The first power line PL1 may receive a first voltage ELVDD. The second power line PL2 may receive a second voltage ELVSS having a lower level than the first voltage ELVDD.

The first transistor T1 may be a PMOS transistor. The second transistor T2 and the third transistor T3 may be NMOS transistors. The first transistor T1 may include a silicon semiconductor, and the second transistor T2 and the third transistor T3 may include an oxide semiconductor.

Each of the first transistor T1, the second transistor T2, and the third transistor T3 may include a source electrode, a drain electrode, and a gate electrode. Hereinafter, in FIG. 7, for convenience, one of the source electrode and the drain electrode is defined as a first electrode, and the other is defined as a second electrode. In addition, the gate electrode is defined as a control electrode.

The first transistor T1 may be defined as a drive transistor, and the second transistor T2 may be defined as a switching transistor. The third transistor T3 may be defined as a compensation transistor.

The first transistor T1 may be connected to the first power line PL1 and the anode AE of the light emitting element OLED and may be switched depending on a voltage of a first node N1. The first transistor T1 may include the first electrode connected to the first power line PL1, the second electrode connected to the anode AE of the light emitting element OLED, and the control electrode connected to the first node N1. The first transistor T1 may be turned on by the voltage of the first node N1. The first node N1 may be substantially defined as the control electrode of the first transistor T1.

The second transistor T2 may be connected to the first node N1 and the second node N2. Specifically, the second transistor T2 may be connected to the gate electrode of the first transistor T1 and the data line DLj. The second transistor T2 may be switched by the write scan signal GWi.

The second transistor T2 may include the first electrode connected to the first node N1, the second electrode connected to the second node N2, and the control electrode connected to the write scan line GWLi. The second transistor T2 may be turned on by the write scan signal GWi applied through the write scan line GWLi.

The third transistor T3 may be connected to the second node N2 and the anode AE of the light emitting element OLED and may be switched by the compensation scan signal GCi. The third transistor T3 may include the first electrode connected to the second node N2, the second electrode connected to the anode AE of the light emitting element OLED, and the control electrode connected to the compensation scan line GCLi. The third transistor T3 may be turned on by the compensation scan signal GCi applied through the compensation scan line GCLi.

The data line DLj may be connected to the second node N2. Accordingly, the data line DLj may be connected to the second electrode of the second transistor T2 and the first electrode of the third transistor T3. The data line DLj may receive a data signal DATA.

The anode AE of the light emitting element OLED may be connected to the first power line PL1 through the first transistor T1, and the cathode CE of the light emitting element OLED may be connected to the second power line PL2.

The capacitor CST may include a first electrode connected to an initialization line VIL and a second electrode connected to the first node N1. The initialization line VIL may receive an initialization voltage VINT.

The write scan signal GWi applied to the control electrode of the second transistor T2 may be a global clock signal for simultaneous emission. For example, when the display device DD operates in a simultaneous emission method, the write scan signal GWi, which is the global clock signal, may be commonly applied to the pixels PX.

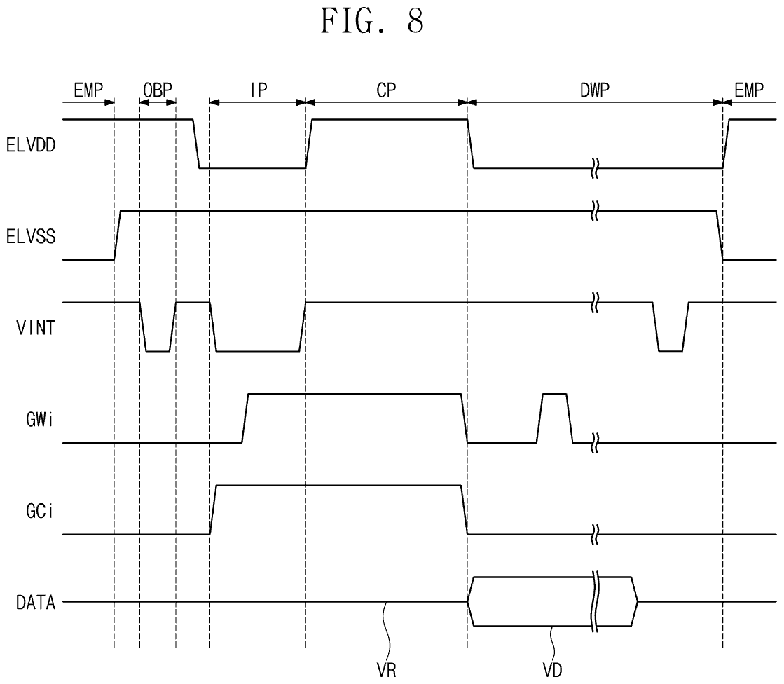

FIG. 8 is a timing chart of signals for operating the pixel illustrated in FIG. 7.

Referring to FIGS. 7 and 8, an operating period of the pixel PXij may include an on-bias period OBP, an initialization period IP, a compensation period CP, a data write period DWP, and an emission period EMP.

The pixel PXij may perform an on-bias operation in the on-bias period OBP and may perform an initialization operation in the initialization period IP. The pixel PXij may perform a threshold voltage compensation operation in the compensation period CP, may perform a data write operation in the data write period DWP, and may perform an emission operation in the emission period EMP.

In the on-bias period OBP, the first voltage ELVDD may have a high voltage level, the second voltage ELVSS may have a high voltage level, and the initialization voltage VINT may have a low voltage level. In the on-bias period OBP, the write scan signal GWi and the compensation scan signal GCi may have a low level (e.g., a deactivation level), and the data signal DATA may have a reference voltage VR having a preset level.

In this case, the on-bias operation may be performed on the pixel PXij, and accordingly the voltage characteristic curve of the first transistor T1 may be initialized to an on-bias state irrespective of the data signal DATA supplied in the previous frame. Thus, the pixel PXij may generate a desired luminance irrespective of the data signal DATA supplied in the previous frame.

In the on-bias period OBP, the initialization voltage VINT having the low voltage level may be transferred to the gate terminal of the first transistor T1, but since both the first voltage ELVDD and the second voltage ELVSS have the high voltage level, the first transistor T1 may not be turned on. The second transistor T2 and the third transistor T3 may be turned off depending on the deactivated write scan signal GWi and the deactivated compensation scan signal GCi.

Thereafter, in the initialization period IP, the first voltage ELVDD may have a low voltage level, the second voltage ELVSS may have a high voltage level, and the initialization voltage VINT may have a low voltage level. In the initialization period IP, the write scan signal GWi may transition from a low level to a high level (e.g., an activation level), the compensation scan signal GCi may have a high level (e.g., an activation level), and the data signal DATA may have the reference voltage VR.

Accordingly, the second transistor T2 may be turned off and then turned on, and the third transistor T3 may be turned on. Since the second transistor T2 and the third transistor T3 are turned on, the first node N1 may be connected to the second node N2, and the second node N2 may be connected to the anode AE of the light emitting element OLED. Depending on the initialization voltage VINT, the first node N1 (that is, the control electrode of the first transistor T1) may be initialized, the second node N2 connected to the first node N1 may be initialized, and the anode AE of the light emitting element OLED connected to the second node N2 may be initialized.

Thereafter, in the compensation period CP, the first voltage ELVDD may have a high voltage level, the second voltage ELVSS may have a high voltage level, and the initialization voltage VINT may have a high voltage level. In the compensation period CP, the write scan signal GWi may have a high level, the compensation scan signal GCi may have a high level, and the data signal DATA may have the reference voltage VR.

The first transistor T1, the second transistor T2, and the third transistor T3 may be connected in the form of a diode. In this case, a voltage reflecting the threshold voltage of the first transistor T1 may be stored in the first node N1, and accordingly the characteristic deviation depending on the threshold voltage of the first transistor T1 may be eliminated. The operation of connecting the first transistor T1 in the form of a diode may be defined as the threshold voltage compensation operation.

Thereafter, in the data write period DWP, the first voltage ELVDD may have a low voltage level, and the second voltage ELVSS may have a high voltage level. In the data write period DWP, the initialization voltage VINT may transition from a high voltage level to a low voltage level and then may transition from the low voltage level to a high voltage level after a certain time elapses.

In the data write period DWP, the write scan signal GWi may transition from a low level to a high level and then may transition from the high level to a low level after a certain time (e.g., a data write operation time) elapses. In the data write period DWP, the compensation scan signal GCi may have a low level, and the data signal DATA may have a data voltage VD having a level corresponding to a certain grayscale.

The second transistor T2 may be turned on during the activation period (e.g., the high level) of the write scan signal GWi, and the third transistor T3 may be turned off. During the data write operation time when the second transistor T2 is turned on, the data signal DATA may be stored in the capacitor CST.

Thereafter, in the emission period EMP, the first voltage ELVDD may have a high voltage level, the second voltage ELVSS may have a low voltage level, and the initialization voltage VINT may have a high voltage level. The write scan signal GWi may have a low level, the compensation scan signal GCi may have a low level, and the data signal DATA may have the reference voltage VR.

In this case, the first transistor T1 may be turned on based on the data signal DATA stored in the capacitor CST. Accordingly, a current may flow to the light emitting element OLED, and the light emitting element OLED may emit light.

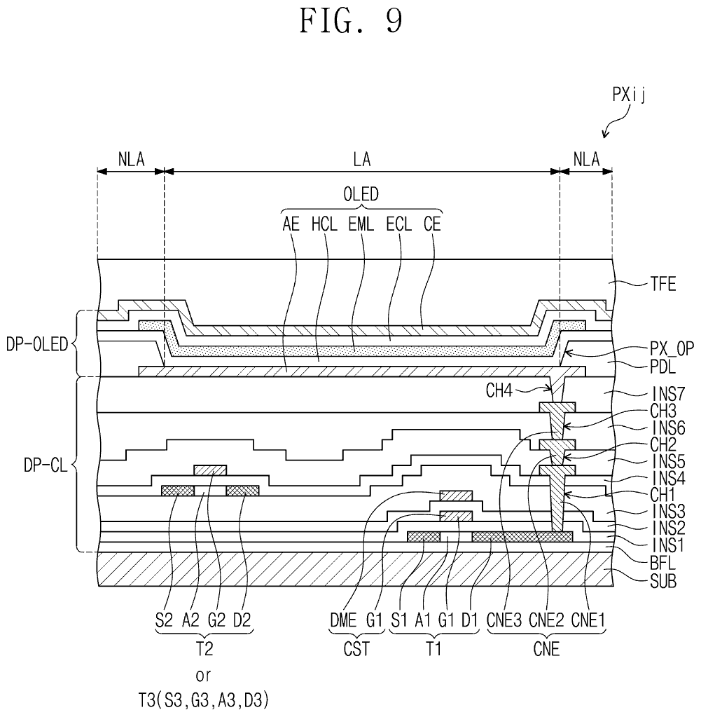

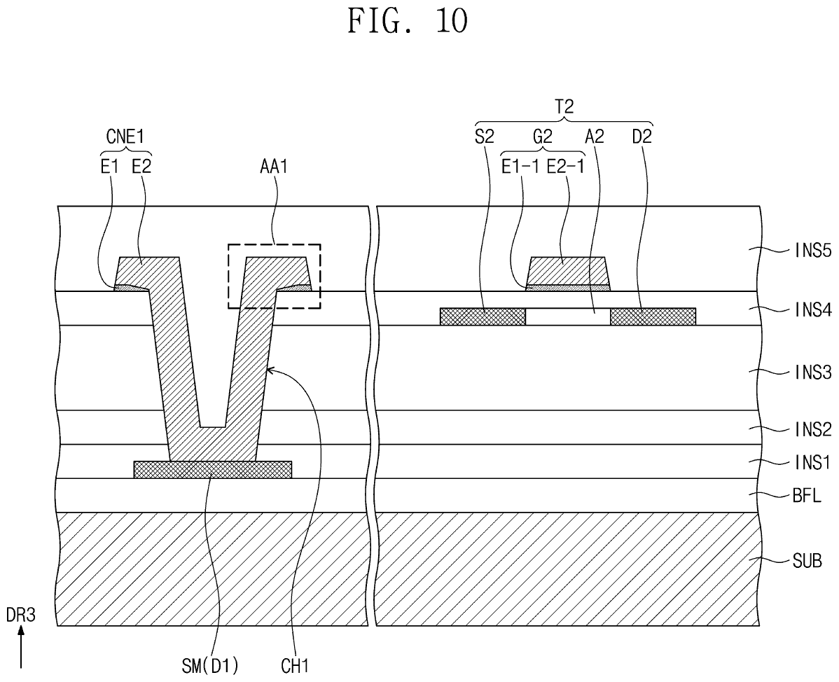

FIG. 9 is a schematic sectional view illustrating the light emitting element, the first transistor, and the second transistor of the pixel illustrated in FIG. 7.

Referring to FIG. 9, the light emitting element OLED may include a first electrode AE, a second electrode CE, a hole control layer HCL, an electron control layer ECL, and an emissive layer EML. The first electrode AE may be the anode AE illustrated in FIG. 7, and the second electrode CE may be the cathode CE illustrated in FIG. 7. The second electrode CE may be disposed over the first electrode AE, and the hole control layer HCL, the electron control layer ECL, and the emissive layer EML may be disposed between the first electrode AE and the second electrode CE.

The first transistor T1, the second transistor T2, and the light emitting element OLED may be disposed on the substrate SUB. The second transistor T2 may be disposed above the first transistor T1, and the light emitting element OLED may be disposed above the second transistor T2. Accordingly, the second transistor T2 may be disposed in a layer between the first transistor T1 and the light emitting element OLED.

The display area DA may include an emissive area LA corresponding to the pixel PXij and a non-emissive area NLA adjacent to the emissive area LA. The light emitting element OLED may be disposed in the emissive area LA.

A buffer layer BFL may be disposed on the substrate SUB. A first semiconductor layer S1, A1, and D1 of the first transistor T1 may be disposed on the buffer layer BFL. The first semiconductor layer S1, A1, and D1 may include poly silicon. However, without being limited thereto, the first semiconductor layer S1, A1, and D1 may include amorphous silicon.

The first semiconductor layer S1, A1, and D1 may include a first source area S1, a first channel area A1, and a first drain area D1. The first channel area A1 may be disposed between the first source area S1 and the first drain area D1. The first source area S1 may correspond to the first electrode of the first transistor T1 described above. The first drain area D1 may correspond to the second electrode of the first transistor T1 described above.

The first source area S1 and the first drain area D1 may have conductivity through a doping process and may substantially serve as the source electrode and the drain electrode of the first transistor T1. The first channel area A1 may substantially correspond to the active of the first transistor T1.

A first insulating layer INS1 may be disposed on the buffer layer BFL to cover the first semiconductor layer S1, A1, and D1. A first gate electrode G1 of the first transistor T1 may be disposed on the first insulating layer INS1. The first gate electrode G1 may overlap the first channel area A1 when viewed from above the plane. The first gate electrode G1 may be the control electrode of the first transistor T1 described above and may be connected to the first node N1. Substantially, the first gate electrode G1 may serve as the first node N1.

A second insulating layer INS2 may be disposed on the first insulating layer INS1 to cover the first gate electrode G1. A dummy electrode DME may be disposed on the second insulating layer INS2. The dummy electrode DME may form the above-described capacitor CST together with the first gate electrode G1. The first gate electrode G1 may define the first electrode of the capacitor CST, and the dummy electrode DME may define the second electrode of the capacitor CST.

A third insulating layer INS3 may be disposed on the second insulating layer INS2 to cover the dummy electrode DME. A second semiconductor layer S2, A2, and D2 of the second transistor T2 may be disposed on the third insulating layer INS3. The second semiconductor layer S2, A2, and D2 may include an oxide semiconductor formed of metal oxide. The oxide semiconductor may include a crystalline or amorphous oxide semiconductor.

The second semiconductor layer S2, A2, and D2 may include a second source area S2, a second channel area A2, and a second drain area D2. The second channel area A2 may be disposed between the second source area S2 and the second drain area D2. The second source area S2 may correspond to the second electrode of the second transistor T2 described above. The second drain area D2 may correspond to the first electrode of the second transistor T2 described above.

The second source area S2 and the second drain area D2 may have conductivity through a doping process and may substantially serve as the source electrode and the drain electrode of the second transistor T2. The second channel area A2 may substantially correspond to the active of the second transistor T2.

A fourth insulating layer INS4 may be disposed on the third insulating layer INS3 to cover the second semiconductor layer S2, A2, and D2. A second gate electrode G2 of the second transistor T2 may be disposed on the fourth insulating layer INS4. The second gate electrode G2 may overlap the second channel area A2 in a plan view. A fifth insulating layer INS5 may be disposed on the fourth insulating layer INS4 to cover the second gate electrode G2.

Although not illustrated, a structure of a third source area S3, a third channel area A3, a third drain area D3, and a third gate electrode G3 of the third transistor T3 disposed in the same layer as the second transistor T2 may be substantially the same as that of the second transistor T2.

The buffer layer BFL and the first to fifth insulating layers INS1 to INS5 may include inorganic layers. For example, the buffer layer BFL and the first insulating layer INS1 may include a silicon oxide layer, and the second insulating layer INS2 may include a silicon nitride layer. The third insulating layer INS3 may include a plurality of inorganic insulating layers that include different materials and that are stacked one above another. For example, the third insulating layer INS3 may include a silicon nitride layer and a silicon oxide layer stacked on each other.

The fourth insulating layer INS4 may include a silicon oxide layer. The fifth insulating layer INS5 may include a plurality of inorganic insulating layers that include different materials and that are stacked one above another. For example, the fifth insulating layer INS5 may include a silicon oxide layer and a silicon nitride layer stacked on each other. The thicknesses of the third insulating layer INS3 and the fifth insulating layer INS5 may be greater than the thicknesses of the buffer layer BFL, the first insulating layer INS1, the second insulating layer INS2, and the fourth insulating layer INS4.

A connecting electrode CNE may be disposed between the first transistor T1 and the light emitting element OLED. The connecting electrode CNE may electrically connect the first transistor T1 and the light emitting element OLED. The connecting electrode CNE may include a first connecting electrode CNE1, a second connecting electrode CNE2 disposed on the first connecting electrode CNE1, and a third connecting electrode CNE3 disposed on the second connecting electrode CNE2.

The first insulating layer INS1 may be disposed on the first semiconductor layer S1, A1, and D1, and the second to fourth insulating layers INS2 to INS4 may be disposed on the first gate electrode G1. Accordingly, the first to fourth insulating layers INS1 to INS4 may be disposed on the first transistor T1. The first to fourth insulating layers INS1 to INS4 may be defined as an insulating layer. That is, the insulating layer may include the plurality of insulating layers INS1 to INS4.

The first connecting electrode CNE1 may be disposed on the fourth insulating layer INS4 and accordingly may be located above the first transistor T1. The first connecting electrode CNE1 may be disposed in the same layer as the second gate electrode G2 of the second transistor T2. The first connecting electrode CNE1 may include the same material as the second gate electrode G2 and may be simultaneously formed with the second gate electrode G2.

The first connecting electrode CNE1 may be connected to the first transistor T1 through a first contact hole CH1 defined in the first to fourth insulating layers INS1 to INS4. The first connecting electrode CNE1 may be connected to the first drain area D1 of the first transistor T1. The fifth insulating layer INS5 may be disposed on the fourth insulating layer INS4 to cover the first connecting electrode CNE1.

The second connecting electrode CNE2 may be disposed on the fifth insulating layer INS5 and may be connected to the first connecting electrode CNE1 through a second contact hole CH2 defined in the fifth insulating layer INS5. A sixth insulating layer INS6 may be disposed on the fifth insulating layer INS5 to cover the second connecting electrode CNE2.

The third connecting electrode CNE3 may be disposed on the sixth insulating layer INS6. The third connecting electrode CNE3 may be connected to the second connecting electrode CNE2 through a third contact hole CH3 defined in the sixth insulating layer INS6. A seventh insulating layer INS7 may be disposed on the sixth insulating layer INS6 to cover the third connecting electrode CNE3. The sixth insulating layer INS6 and the seventh insulating layer INS7 may include an organic layer.

The first electrode AE may be disposed on the seventh insulating layer INS7. Accordingly, the first electrode AE may be disposed on the first connecting electrode CNE1, the second connecting electrode CNE2, and the third connecting electrode CNE3. The first electrode AE may be electrically connected to the third connecting electrode CNE3 through a fourth contact hole CH4 defined in the seventh insulating layer INS7. Accordingly, the first connecting electrode CNE1 may be connected to the first electrode AE through the second connecting electrode CNE2 and the third connecting electrode CNE3.

A pixel defining layer PDL exposing a certain portion of the first electrode AE may be disposed on the first electrode AE and the seventh insulating layer INS7. An opening PX_OP for exposing the certain portion of the first electrode AE may be defined in the pixel defining layer PDL.

The hole control layer HCL may be disposed on the first electrode AE and the pixel defining layer PDL. The hole control layer HCL may be commonly disposed in the emissive area LA and the non-emissive area NLA. The hole control layer HCL may include a hole transport layer and a hole injection layer.

The emissive layer EML may be disposed on the hole control layer HCL. The emissive layer EML may be disposed in an area corresponding to the opening PX_OP. The emissive layer EML may include an organic material and/or an inorganic material. The emissive layer EML may generate one of red light, green light, and blue light.

The electron control layer ECL may be disposed on the emissive layer EML and the hole control layer HCL. The electron control layer ECL may be commonly disposed in the emissive area LA and the non-emissive area NLA. The electron control layer ECL may include an electron transport layer and an electron injection layer.

The second electrode CE may be disposed on the electron control layer ECL. The second electrode CE may be commonly disposed in the pixels PX. That is, the second electrode CE may be commonly disposed over the emissive layers EML of the pixels PX.

The layers from the buffer layer BFL to the seventh insulating layer INS7 may be defined as the circuit element layer DP-CL. The layer in which the light emitting element OLED is disposed may be defined as the display element layer DP-OLED.

The thin film encapsulation layer TFE may be disposed on the light emitting element OLED. The thin film encapsulation layer TFE may include an inorganic layer, an organic layer, and an inorganic layer sequentially stacked one above another. The inorganic layers may include an inorganic material and may protect the pixels from moisture/oxygen. The organic layer may include an organic material and may protect the pixels PX from foreign matter such as dust particles.

The first voltage ELVDD may be applied to the first electrode AE, and the second voltage EVLSS may be applied to the second electrode CE. Holes and electrons injected into the emissive layer EML may be combined to form excitons, and the light emitting element OLED may emit light as the excitons transition to a ground state. An image may be displayed as the light emitting element OLED emits the light.

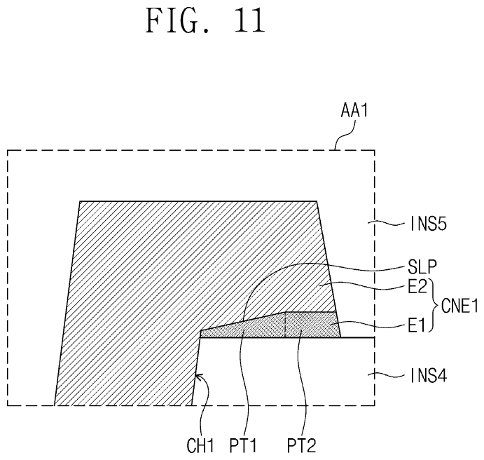

FIG. 10 is an enlarged sectional view of the first connecting electrode, the semiconductor layer connected to the first connecting electrode, and the second transistor illustrated in FIG. 9. FIG. 11 is an enlarged view of a first area AA1 illustrated in FIG. 10.

Hereinafter, the first drain area D1 of the first transistor T1 connected to the first connecting electrode CNE1 is defined as a semiconductor layer SM. In FIG. 10, for convenience of description, the first connecting electrode CNE1 is disposed to the left of the second transistor T2, and the insulating layers INS1 to INS5 are illustrated in a flat state. For example, in FIG. 10, the first connecting electrode CNE1, the first drain area D1, and the second transistor T2 are illustrated, and the other components of the pixel PXij illustrated in FIG. 9 are omitted.

Referring to FIG. 10, the first connecting electrode CNE1 may be disposed within the first contact hole CH1. In addition, the first connecting electrode CNE1 may be disposed on a portion of the fourth insulating layer INS4 that is adjacent to the first contact hole CH1.

The first connecting electrode CNE1 may include a first electrode E1 and a second electrode E2. The first electrode E1 may be disposed on the portion of the fourth insulating layer INS4 that is adjacent to the first contact hole CH1. The first electrode E1 may not be disposed within the first contact hole CH1.

The second electrode E2 may be disposed on the first electrode E1 and within the first contact hole CH1. The second electrode E2 may be disposed within the first contact hole CH1 and may be connected to the semiconductor layer SM of the first transistor T1.

The first electrode E1 and the second electrode E2 may include different materials. For example, the first electrode E1 may include titanium (Ti), and the second electrode E2 may include molybdenum (Mo).

The second electrode E2 may have a thickness greater than a thickness of the first electrode E1. For example, the first electrode E1 may have a thickness of several hundred angstroms (Å).

In this specification, “thickness” may be defined as a numerical value measured in the third direction DR3 described above. The third direction DR3 may be defined as a direction extending substantially perpendicular to the flat upper surface of the first to fifth insulating layers INS1 to INS5. The flat upper surface may be defined by the first direction DR1 and the second direction DR2.

Referring to FIG. 11, the upper surface of a portion of the first electrode E1 that is adjacent to the first contact hole CH1 may have an inclined surface SLP. The inclined surface SLP may form a certain angle with the flat upper surface of the first to fifth insulating layers INS1 to INS5. The angle may be less than 90 degrees and greater than 0 degrees.

The first electrode E1 may include a first portion PT1 having an upper surface that is the inclined surface SLP and a second portion PT2 having a flat upper surface. For example, the boundary between the first portion PT1 and the second portion PT2 is illustrated by a dotted line in FIG. 11. The first portion PT1 may be adjacent to the first contact hole CH1, and the second portion PT2 may be spaced further apart from the first contact hole CH1 when compared to the first portion PT1.

Referring to FIG. 10, the second gate electrode G2 may include a first-first electrode E1-1 and a second-first electrode E2-1. The first-first electrode E1-1 may be disposed on the fourth insulating layer INS4, and the second-first electrode E2-1 may be disposed on the first-first electrode E1-1.

The first-first electrode E1-1 may be disposed in the same layer as the first electrode E1 and may have the same configuration as the first electrode E1. For example, the first-first electrode E1-1 may include the same material as the first electrode E1 and may include titanium (Ti). The first-first electrode E1-1 may be simultaneously subjected to patterning together with the first electrode E1.

The second-first electrode E2-1 may be disposed in the same layer as the second electrode E2 and may have the same configuration as the second electrode E2. For example, the second-first electrode E2-1 may include the same material as the second electrode E2 and may include molybdenum (Mo). Accordingly, the thickness of the second-first electrode E2-1 may be greater than the thickness of the first-first electrode E1-1. The second-first electrode E2-1 may be simultaneously subjected to patterning together with the second electrode E2.

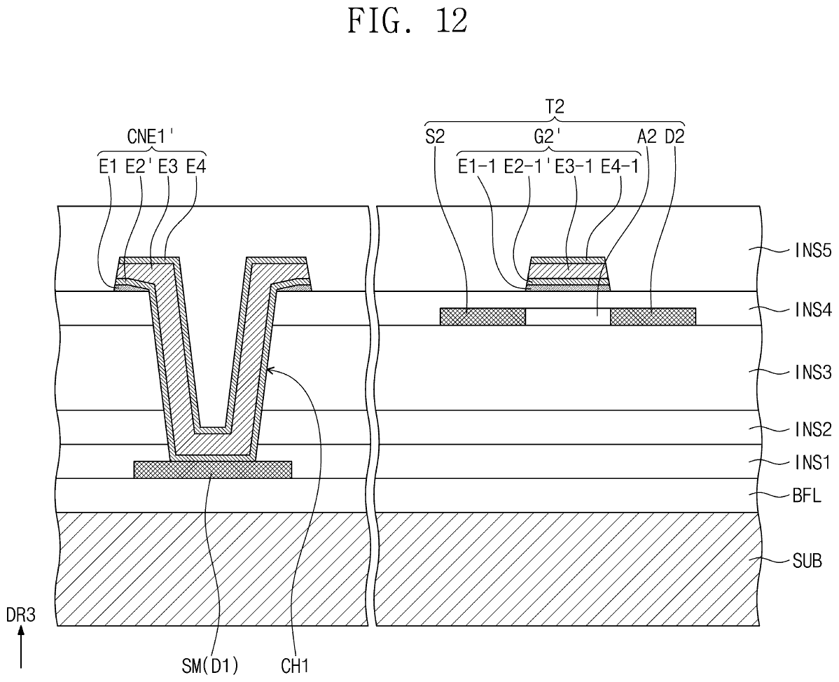

FIG. 12 is a view illustrating a cross-sectional configuration of a first connecting electrode and a second gate electrode according to an embodiment of the present disclosure.

For example, FIG. 12 is a sectional view corresponding to FIG. 10. Hereinafter, the components illustrated in FIG. 12 will be described focusing on components different from the components illustrated in FIG. 10.

Referring to FIG. 12, the first connecting electrode CNE1′ may include a first electrode E1, a second electrode E2′, a third electrode E3, and a fourth electrode E4. The first electrode E1 may be disposed on a portion of the fourth insulating layer INS4 that is adjacent to the first contact hole CH1 and may not be disposed within the first contact hole CH1. The first electrode E1 may be the same as the first electrode E1 illustrated in FIGS. 10 and 11.

The second electrode E2′ may be disposed on the first electrode E1 and within the first contact hole CH1. The third electrode E3 may be disposed on the second electrode E2′, and the fourth electrode E4 may be disposed on the third electrode E3.

The first electrode E1, the second electrode E2′, and the fourth electrode E4 may include the same material. The third electrode E3 may include a material different from the material of the first electrode E1, the second electrode E2′, and the fourth electrode E4. For example, the first electrode E1, the second electrode E2′, and the fourth electrode E4 may include titanium (Ti), and the third electrode E3 may include aluminum (A1).

The first electrode E1, the second electrode E2′, and the fourth electrode E4 may have the same thickness or different thicknesses. The thickness of the third electrode E3 may be greater than the thickness of each of the first electrode E1, the second electrode E2′, and the fourth electrode E4.

A gate electrode G2′ may include a first-first electrode E1-1, a second-first electrode E2-1′, a third-first electrode E3-1, and a fourth-first electrode E4-1. The first-first electrode E1-1 may be the same as the first-first electrode E1-1 illustrated in FIG. 10.

The first-first electrode E1-1 may be disposed on the fourth insulating layer INS4, and the second-first electrode E2-1′ may be disposed on the first-first electrode E1-1. The third-first electrode E3-1 may be disposed on the second-first electrode E2-1′, and the fourth-first electrode E4-1 may be disposed on the third-first electrode E3-1.

The first-first electrode E1-1 may be disposed in the same layer as the first electrode E1 and may have the same configuration as the first electrode E1. For example, the first-first electrode E1-1 may include the same material as the first electrode E1 and may include titanium (Ti).

The second-first electrode E2-1′ may be disposed in the same layer as the second electrode E2′ and may have the same configuration as the second electrode E2′. For example, the second-first electrode E2-1′ may include the same material as the second electrode E2′ and may include titanium (Ti). The second-first electrode E2-1′ may be simultaneously subjected to patterning together with the second electrode E2′.

The third-first electrode E3-1 may be disposed in the same layer as the third electrode E3 and may have the same configuration as the third electrode E3. For example, the third-first electrode E3-1 may include the same material as the third electrode E3 and may include aluminum (A1). The third-first electrode E3-1 may be simultaneously subjected to patterning together with the third electrode E3.

The fourth-first electrode E4-1 may be disposed in the same layer as the fourth electrode E4 and may have the same configuration as the fourth electrode E4. For example, the fourth-first electrode E4-1 may include the same material as the fourth electrode E4 and may include titanium (Ti). The fourth-first electrode E4-1 may be simultaneously subjected to patterning together with the fourth electrode E4.

The thickness of the third-first electrode E3-1 may be greater than the thickness of each of the first-first electrode E1-1, the second-first electrode E2-1′, and the fourth-first electrode E4-1. In addition, the first-first electrode E1-1, the second-first electrode E2-1′, and the fourth-first electrode E4-1 may have the same thickness or different thicknesses.

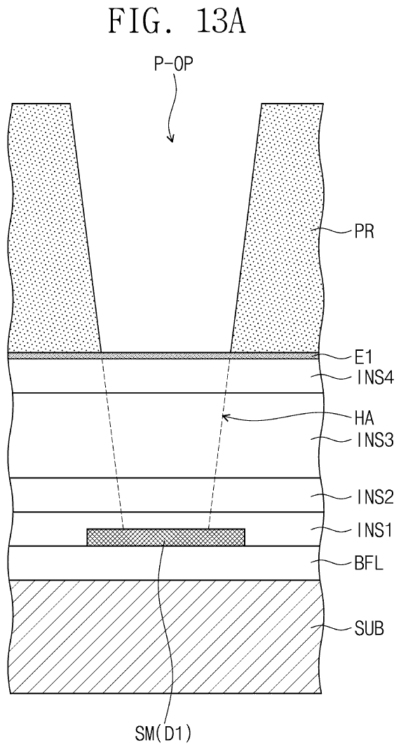

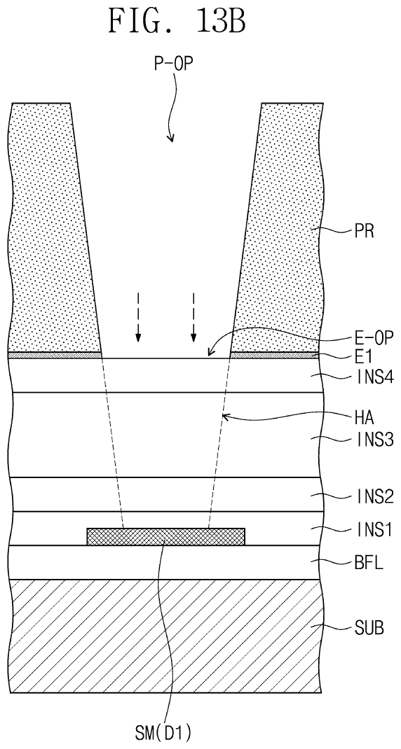

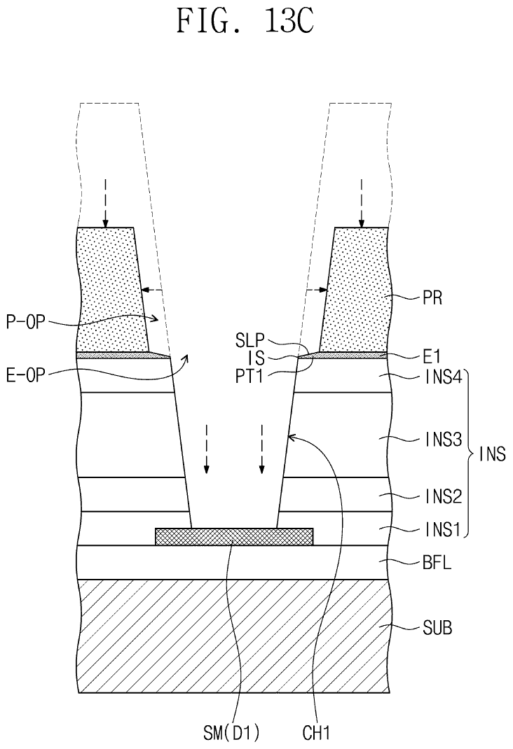

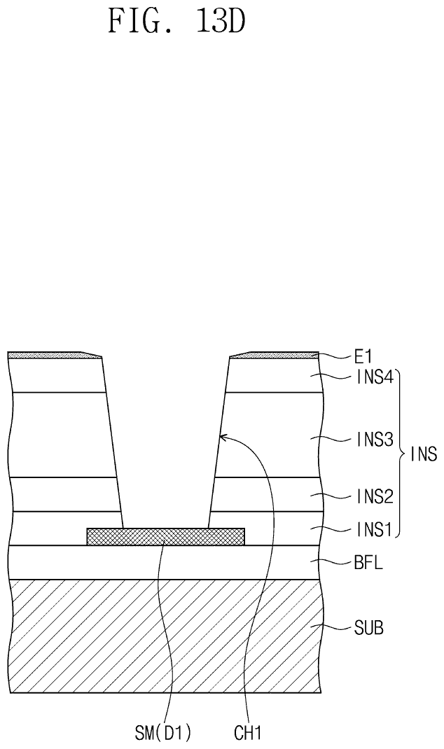

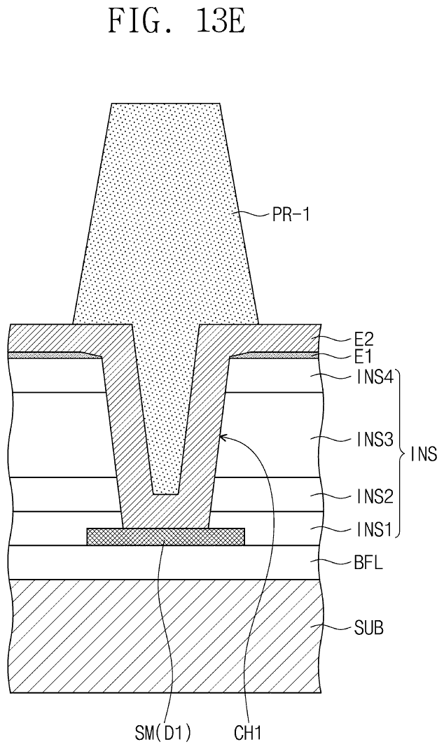

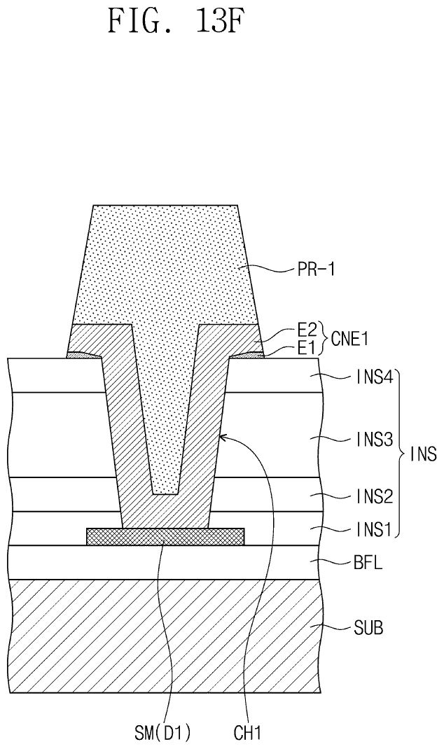

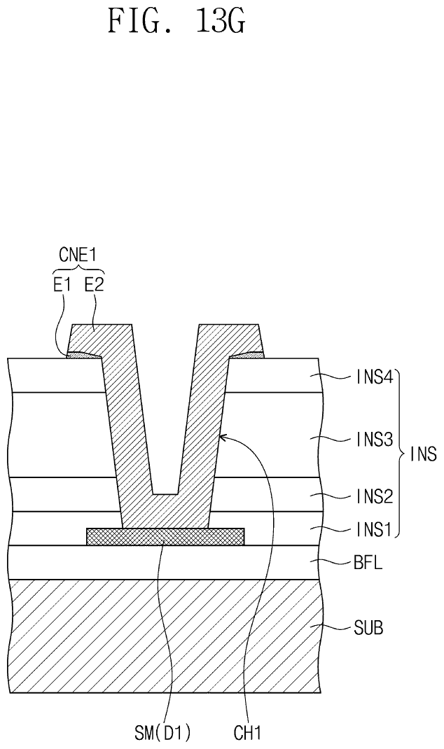

FIGS. 13A to 13G are views for explaining a method of manufacturing the display device including the first connecting electrode illustrated in FIG. 10.

For example, FIGS. 13A to 13G may correspond to a cross-section of the portion where the first connecting electrode CNE1 illustrated in FIG. 10 is disposed.

Referring to FIGS. 9 and 13A, the first transistor T1 may be provided on the substrate SUB, and the first to fourth insulating layers INS1 to INS4 may be provided on the first transistor T1. A hole area HA may be defined in the first to fourth insulating layers INS1 to INS4. The hole area HA may be an area overlapping the first contact hole CH1 described above in a plan view. The hole area HA may be defined as an area substantially removed by an etching process.

The first electrode E1 may be provided on the fourth insulating layer INS4, and a photoresist layer PR may be provided on the first electrode E1. An opening P-OP overlapping the hole area HA in a plan view may be defined in the photoresist layer PR.

Referring to FIG. 13B, a portion of the first electrode E1 that overlaps the hole area HA in a plan view may be removed using the photoresist layer PR as a mask. For example, the portion of the first electrode E1 that overlaps the hole area HA in a plan view may be etched through a dry etching process. An opening E-OP overlapping the hole area HA may be defined in the first electrode E1 by removing the portion of the first electrode E1 that overlaps the hole area HA in a plan view.

Chlorine gas (Cl₂ gas) and argon gas (Ar gas) may be used when the etching process is performed on the first electrode E1. In addition, fluorocarbon gas may be additionally used when the etching process is performed on the first electrode E1.

Referring to FIG. 13C, the hole area HA of the first to fourth insulating layers INS1 to INS4 may be removed using the first electrode E1 and the photoresist layer PR as a mask. Hereinafter, the first to fourth insulating layers INS1 to INS4 may be defined as an insulating layer INS.

The hole area HA may be removed by an etching gas injected into the insulating layer INS through the opening E-OP defined in the first electrode E1. The first contact hole CH1 may be defined in the insulating layer INS by removing the hole area HA. A portion of the semiconductor layer SM may be exposed by the first contact hole CH1.

For example, the hole area HA may be removed through a dry etching process. When the etching process is performed on the insulating layer INS, fluorocarbon gas may be used, but chlorine gas (Cl₂ gas) and argon gas (Ar gas) may not be used.

A portion of the photoresist layer PR may also be removed by the etching gas used when the etching process is performed on the first to fourth insulating layers INS1 to INS4. Accordingly, unlike in FIG. 13B, the thickness and width of the photoresist layer PR may be reduced as illustrated in FIG. 13C. Since the width of the photoresist layer PR is reduced, the width of the opening P-OP may be increased.

When the etching process is performed on the first electrode E1, a portion of the photoresist layer PR may be removed by the etching gases. However, since the etching process for the first electrode E1 having a very small thickness is performed in a short time, the portion removed from the photoresist layer PR by the etching gases may be very small. In consideration of the etched state of the photoresist layer PR, the thickness and width of the photoresist layer PR in FIG. 13B are illustrated to be substantially the same as the thickness and width of the photoresist layer PR in FIG. 13A.

However, since the etching process for the insulating layer INS having a very large thickness requires a long time, a larger portion may be removed from the photoresist layer PR by the etching gas. In consideration of the etched state of the photoresist layer PR, the thickness and width of the photoresist layer PR in FIG. 13C are illustrated to be smaller than the thickness and width of the photoresist layer PR in FIG. 13B. For example, in FIG. 13C, the photoresist layer PR before the removal of the portion and the photoresist layer PR after the removal of the portion are illustrated by a dotted line and a solid line so as to be distinguished from each other.

When the fluorocarbon gas is used to etch the insulating layer INS, the etch rate of the first electrode E1 including titanium may be lower than the etch rate of the insulating layer INS. For example, the ratio between the etch rate of the first electrode E1 by the fluorocarbon gas and the etch rate of the insulating layer INS by the fluorocarbon gas may range from 1:10 to 1:70.

Accordingly, even though the width of the photoresist layer PR is reduced so that a portion of the first electrode E1 adjacent to the hole area HA is exposed, only a very small portion of the first electrode E1 may be etched. For example, only an upper part of the portion of the first electrode E1 exposed due to the reduction in the width of the photoresist layer PR may be removed, and the width of the opening E-OP may be maintained as it is.

The portion of the first electrode E1 exposed due to the reduction in the width of the photoresist layer PR may be the first portion PT1. An upper part of the first portion PT1 may be removed by the etching gas so that the upper surface of the first portion PT1 may have the inclined surface SLP.

As the width of the photoresist layer PR is reduced in the left-right direction, the width of the opening P-OP may be gradually increased. The first portion PT1 of the first electrode E1 may be gradually exposed from an inner surface IS of the first electrode E1 that defines the opening E-OP. Accordingly, exposure time at the first portion PT1 may be increased with an approach to the inner surface IS of the first electrode IS. In this case, the amount that the first portion PT1 is etched may be increased with an approach to the inner surface IS of the first electrode E1, and accordingly the upper surface of the first portion PT1 may be formed of the inclined surface SLP.

Referring to FIG. 13D, the photoresist layer PR may be removed. Accordingly, the first electrode E1 may be exposed.

Referring to FIG. 13E, the second electrode E2 may be provided on the first electrode E1 and within the first contact hole CH1. The second electrode E2 may be disposed within the first contact hole CH1 and may make contact with the portion of the semiconductor layer SM exposed by the first contact hole CH1. Accordingly, the second electrode E2 may be electrically connected to the semiconductor layer SM.

A photoresist layer PR-1 may be provided on the second electrode E2. The photoresist layer PR-1 may overlap the first contact hole CH1 and a portion of the insulating layer INS that is adjacent to the first contact hole CH1 in a plan view. That is, the photoresist layer PR-1 may overlap the second electrode E2 disposed within the first contact hole CH1 and portions of the first electrode E1 and the second electrode E2 that are adjacent to the first contact hole CH1 in a plan view.

Referring to FIG. 13F, a dry etching process may be performed using the photoresist layer PR-1 as a mask. By the etching process, portions of the first electrode E1 and the second electrode E2 that overlap the photoresist layer PR-1 in a plan view may remain, and the remaining portions of the first electrode E1 and the second electrode E2 that do not overlap the photoresist layer PR-1 in a plan view may be removed.

That is, a portion of the second electrode E2 disposed within the first contact hole CH1 and portions of the first electrode E1 and the second electrode E2 disposed on the portion of the insulating layer INS that is adjacent to the first contact hole CH1 may remain, and the remaining portions of the first electrode E1 and the second electrode E2 may be removed. The first connecting electrode CNE1 may include the remaining first electrode E1 and the remaining second electrode E2.

Referring to FIG. 13G, the photoresist layer PR-1 may be removed. Thereafter, the second connecting electrode CNE2, the third connecting electrode CNE3, and the light emitting element OLED illustrated in FIG. 9 may be provided on the first connecting electrode CNE1. As illustrated in FIG. 9, the first connecting electrode CNE1 may be connected to the first electrode AE of the light emitting element OLED through the second connecting electrode CNE2 and the third connecting electrode CNE3.

Although not illustrated, the second transistor T2 may be provided above the first transistor T1 before the light emitting element OLED is provided above the first transistor T1.

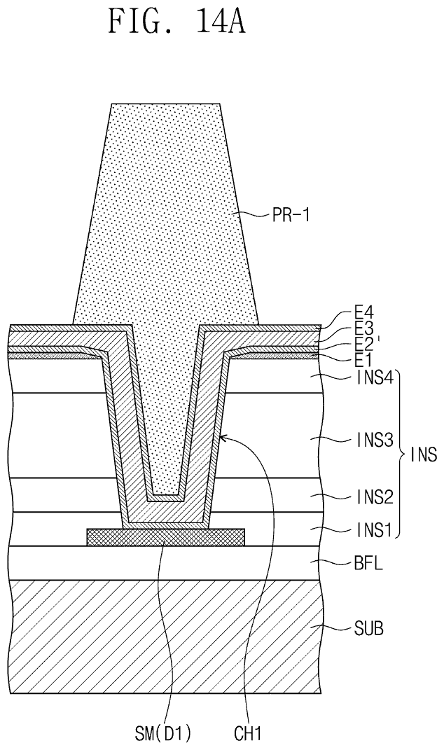

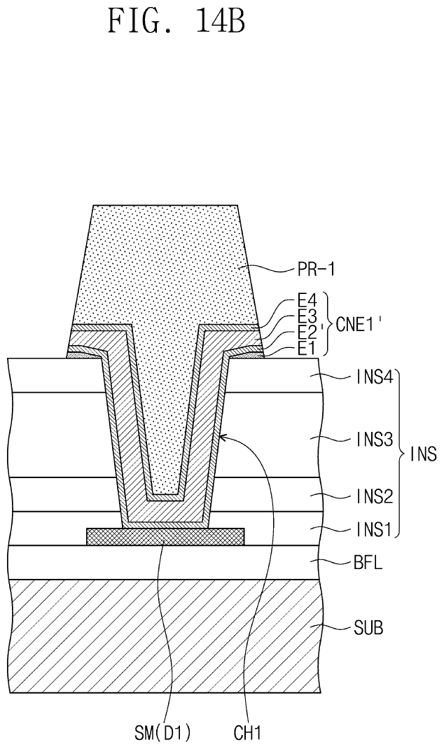

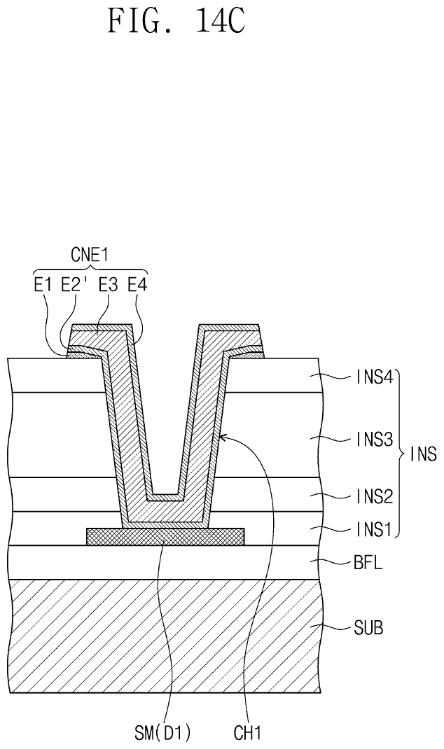

FIGS. 14A to 14C are views for explaining a method of manufacturing the display device including the first connecting electrode illustrated in FIG. 12.

For example, FIGS. 14A to 14C may correspond to a cross-section of the portion where the first connecting electrode CNE1′ illustrated in FIG. 12 is disposed.

A method of forming the first contact hole CH1 using the first electrode E1, which has the opening E-OP formed therein, as a mask when forming the first connecting electrode CNE1′ may be the same as that in FIGS. 13A to 13D.

Referring to FIG. 14A, the second electrode E2′ may be provided on the first electrode E1 and within the first contact hole CH1 after the first contact hole CH1 is formed. The second electrode E2′ may be electrically connected to the semiconductor layer SM through the first contact hole CH1. The third electrode E3 may be provided on the second electrode E2′, and the fourth electrode E4 may be provided on the third electrode E3.

A photoresist layer PR-1 may be provided on the fourth electrode E4. The photoresist layer PR-1 may overlap the first contact hole CH1 and a portion of the insulating layer INS that is adjacent to the first contact hole CH1 in a plan view. That is, the photoresist layer PR-1 may overlap the second to fourth electrodes E2′ to E4 disposed within the first contact hole CH1 and portions of the first to fourth electrodes E1 to E4 that are adjacent to the first contact hole CH1 in a plan view.

Referring to FIG. 14B, a dry etching process may be performed using the photoresist layer PR-1 as a mask. By the etching process, portions of the first to fourth electrodes E1 to E4 that overlap the photoresist layer PR-1 in a plan view may remain, and the remaining portions of the first to fourth electrodes E1 to E4 that do not overlap the photoresist layer PR-1 in a plan view may be removed.

That is, portions of the second, third, and fourth electrodes E2′, E3 and E4 disposed within the first contact hole CH1 and portions of the first, second, third, and fourth electrodes E1, E2′, E3 and E4 disposed on the portion of the insulating layer INS that is adjacent to the first contact hole CH1 may remain, and the remaining portions of the first, second, third, and fourth electrodes E1, E2′, E3 and E4 may be removed. The first connecting electrode CNE1′ may include the first, second, third, and fourth electrodes E1, E2′, E3 and E4 that remain.

Referring to FIG. 14C, the photoresist layer PR-1 may be removed. Thereafter, the second connecting electrode CNE2, the third connecting electrode CNE3, and the light emitting element OLED illustrated in FIG. 9 may be provided on the first connecting electrode CNE1′, and the first connecting electrode CNE1′ may be connected to the first electrode AE of the light emitting element OLED through the second connecting electrode CNE2 and the third connecting electrode CNE3.

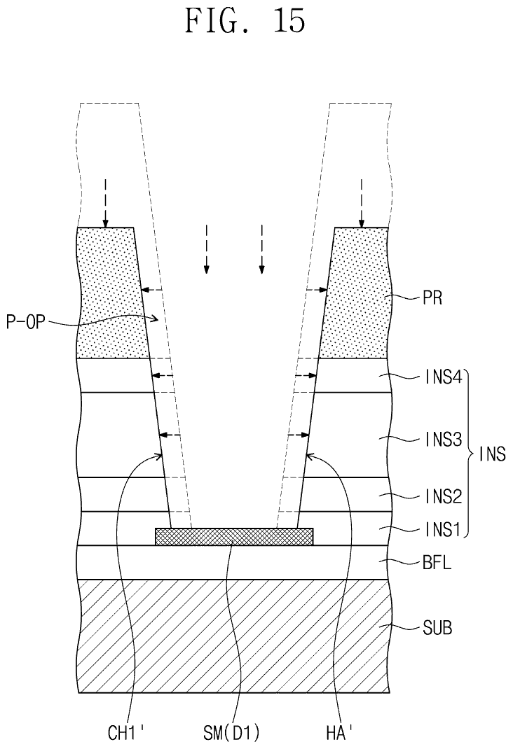

FIG. 15 is a view illustrating a first contact hole formed by an etching process when the first electrode is not used in FIG. 13C.

Referring to FIG. 15, as described with reference to FIG. 13, the width of the opening P-OP may be increased due to the reduction in the width of the photoresist layer PR. Accordingly, a hole area HA′ removed using the photoresist layer PR as a mask may be made larger. Thus, the size of the first contact hole CH1′ formed by removing the hole area HA′ may be increased. That is, the first contact hole CH1′ may not be formed in a desired size.

However, in an embodiment of the present disclosure, as illustrated in FIG. 13C, the first electrode E1 may be used as a mask, and accordingly the first contact hole CH1 may be formed in a desired size. Thus, the first contact hole CH1 may be more precisely manufactured.

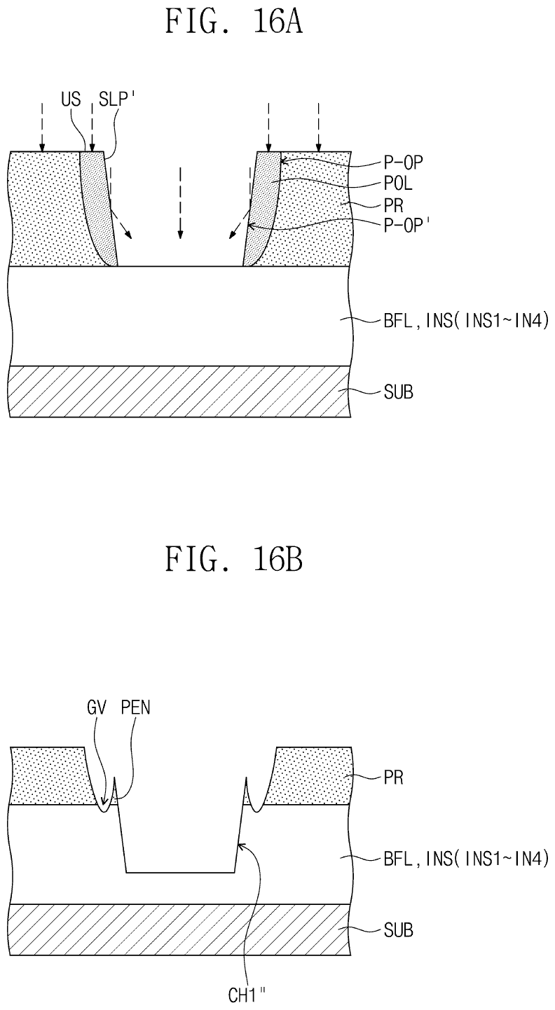

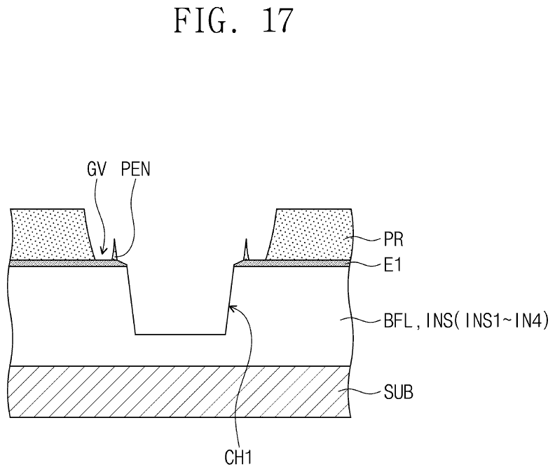

FIGS. 16A and 16B are views illustrating a fence structure depending on a polymer layer disposed on an inner surface of a photoresist layer.

For example, in FIGS. 16A and 16B, the buffer layer BFL and the first to fourth insulating layers INS1 to INS4 are illustrated as a single layer, and the semiconductor layer SM is omitted.

Referring to FIG. 16A, when the opening P-OP is formed in the photoresist layer PR, the inner surface that forms the opening P-OP may have a concave curved surface. Due to the curved surface, an etching process may not be normally performed. Accordingly, the polymer layer POL may be additionally deposited on the concave inner surface of the photoresist layer PR. The polymer layer POL may fill the concave inner surface of the photoresist layer PR.

An opening P-OP′ may be defined by the polymer layer POL. An etching process may be performed using the photoresist layer PR and the polymer layer POL as a mask.

Referring to FIGS. 16A and 16B, a first contact hole CH1″ may be defined in the insulating layer INS by the etching process. When the etching process is performed on the insulating layer INS, the etch rate of the polymer layer POL may be higher than the etch rate of the photoresist layer PR. In addition, in the etching process, ion particles may be provided to an upper surface US of the polymer layer POL and an inclined surface SLP′ of the polymer layer POL. The ion particles provided to the inclined surface SLP′ of the polymer layer POL may be reflected by the inclined surface SLP′.

Accordingly, the amount of ion particles provided to the upper surface US of the polymer layer POL may be larger than the amount of ion particles provided to the inclined surface SLP′ of the polymer layer POL. Thus, the upper surface US of the polymer layer POL may be more rapidly etched than the inclined surface SLP′ of the polymer layer POL. In this case, the inclined surface SLP′ of the polymer layer POL may remain in the form of a fence PEN, and the upper surface US of the polymer layer POL may be rapidly etched downward to form a groove GV. A portion of the insulating layer INS exposed through the groove GV may be etched, and therefore an unintended defect may occur.

FIG. 17 is a view illustrating a configuration in which the first electrode of the first connecting electrode described above is used in the fence structure illustrated in FIG. 16B.

Referring to FIG. 17, even though the fence PEN and the groove GV illustrated in FIG. 16B are formed, the first electrode E1 may block an etching gas, and thus the portion of the insulating layer INS that overlaps the groove GV in a plan view may not be etched.

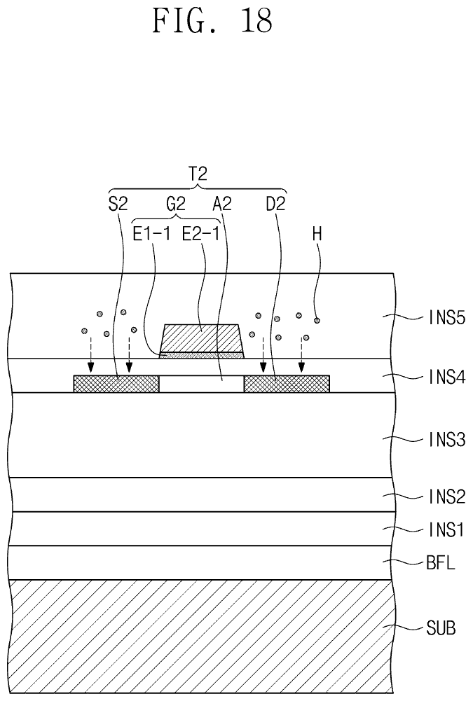

FIG. 18 is a view for explaining a hydrogen implantation process for the second semiconductor layer of the second transistor illustrated in FIG. 10.

For example, in FIG. 18, only the second transistor T2 illustrated in FIG. 10 is illustrated, and the other components are omitted.

Referring to FIG. 18, the fifth insulating layer INS5 may be disposed on the second gate electrode G2 after a doping process is performed on the second semiconductor layer S2, A2, and D2 using the second gate electrode G2 as a mask. The fifth insulating layer INS5, which is an inorganic layer, may contain hydrogen (H). The hydrogen (H) in the fifth insulating layer INS5 may be released from the fifth insulating layer INS5 through an annealing process.

The hydrogen (H) released from the fifth insulating layer INS5 may be provided to the second source area S2 and the second drain area D2. When the hydrogen (H) is implanted into the second source area S2 and the second drain area D2 that are oxide semiconductors, the conductivities of the second source area S2 and the second drain area D2 may be further increased. To improve the conductivities of the second source area S2 and the second drain area D2, the hydrogen (H) in the fifth insulating layer INS5 may be implanted into the second source area S2 and the second drain area D2.

When the hydrogen (H) is provided to the second channel area A2, the conductivity of the second channel area A2 may be increased, and therefore the second channel area A2 may not function as an active. The first-first electrode E1-1 may be used to block the hydrogen (H). Titanium (Ti) may more effectively block the hydrogen (H) than other metals. That is, titanium (Ti) may block the hydrogen (H) better than the other metals.

In an embodiment of the present disclosure, the first-first electrode E1-1 and the first electrode E1 may be simultaneously formed of titanium (Ti). The first-first electrode E1-1 including titanium (Ti) may be directly disposed on the upper surface of the fourth insulating layer INS4 and accordingly may be disposed adjacent to the second channel area A2. The first-first electrode E1-1 may more effectively block the hydrogen (H) such that the hydrogen (H) released from the fifth insulating layer INS5 is not provided to the second channel area A2. Accordingly, the second channel area A2 may normally function as an active.

The first-first electrode E1-1 and the first electrode E1 may be simultaneously formed of another metal other than titanium. However, since the hydrogen blocking rate of the first-first electrode E1-1 including the other metal is decreased in this case, an additional electrode including titanium may be disposed on the first-first electrode E1-1.

The additional electrode including titanium may not be directly disposed on the upper surface of the fourth insulating layer INS4 and accordingly may be spaced further apart from the second channel area A2. When the gap between the second channel area A2 and the additional electrode including titanium is increased, there may be a high possibility that the hydrogen H will diffuse into the second channel area A2.

In an embodiment of the present disclosure, the first-first electrode E1-1 including titanium (Ti) may be directly disposed on the upper surface of the fourth insulating layer INS4 and accordingly may be disposed closer to the second channel area A2. In this case, a possibility that the hydrogen H will diffuse into the second channel area A2 may be effectively reduced.

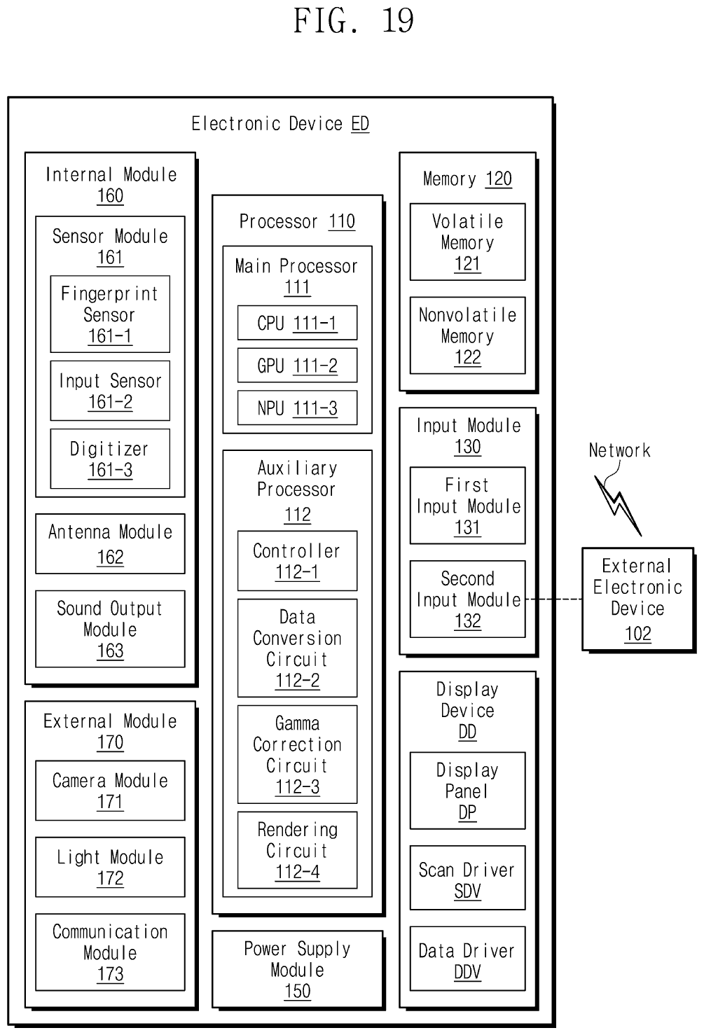

FIG. 19 is a block diagram of an electronic device including the display device according to an embodiment of the present disclosure.

Referring to FIG. 19, the electronic device ED may output a variety of information through the display device DD in an operating system. When a processor 110 executes an application stored in a memory 120, the display device DD may provide a user with application information through the display panel DP.

The processor 110 obtains an external input through an input module 130 or a sensor module 161 and executes an application corresponding to the external input. For example, when the user selects a camera icon displayed on the display panel DP, the processor 110 obtains the user input through an input sensor 161-2 and activates a camera module 171. The processor 110 transfers image data corresponding to a photographed image obtained through the camera module 171 to the display device DD. The display device DD may display an image corresponding to the photographed image through the display panel DP.

In another example, when authentication for personal information is performed in the display device DD, a fingerprint sensor 161-1 obtains input fingerprint information as input data. The processor 110 compares the input data obtained through the fingerprint sensor 161-1 with authentication data stored in the memory 120 and executes an application depending on a comparison result. The display device DD may display information executed depending on logic of the application, through the display panel DP.

In another example, when the user selects a music streaming icon displayed on the display device DD, the processor 110 obtains the user input through the input sensor 161-2 and activates a music streaming application stored in the memory 120. When a music play command is input to the music streaming application, the processor 110 activates a sound output module 163 and provides the user with sound information corresponding to the music play command.

The operation of the electronic device ED has been briefly described above. Hereinafter, a configuration of the electronic device ED will be described in detail. Some of the components of the electronic device ED to be described below may be integrally implemented with one component, and the one component may be divided into two or more components.

The electronic device ED may communicate with an external electronic device 102 over a network (e.g., a short-range wireless communication network or a long-range wireless communication network). According to an embodiment, the electronic device ED may include the processor 110, the memory 120, the input module 130, the display device DD, a power supply module 150, an internal module 160, and an external module 170. According to an embodiment, the electronic device ED may not include at least one of the above components or may further include one or more other components. According to an embodiment, some of the above components (e.g., the sensor module 161, an antenna module 162, or the sound output module 163) may be integrated into any other component (e.g., the display device DD).

The processor 110 may execute software to control at least one other component (e.g., a hardware or software component) of the electronic device ED connected to the processor 110 and may perform various data processing or operations. According to an embodiment, as at least a part of the data processing or operations, the processor 110 may store a command or data received from any other component (e.g., the input module 130, the sensor module 161, or a communication module 173) in a volatile memory 121, may process the command or data stored in the volatile memory 121, and may store the processed data in a nonvolatile memory 122.

The processor 110 may include a main processor 111 and an auxiliary processor 112. The main processor 111 may include one or more of a central processing unit (“CPU”) 111-1 or an application processor (“AP”). The main processor 20 111 may further include one or more of a graphic processing unit (“GPU”) 111-2, a communication processor (“CP”), and an image signal processor (“ISP”).

The main processor 111 may further include a neural processing unit (“NPU”) 111-3. The neural processing unit 111-3 may be a processor specialized for processing of an artificial intelligence model, and the artificial intelligence model may be created through machine learning. The artificial intelligence model may include a plurality of artificial neural network layers.

The artificial neural network may include one of a deep neural network (“DNN”), a convolutional neural network (“CNN”), a recurrent neural network (“RNN”), a restricted Boltzmann machine (“RBM”), a deep belief network (“DBN”), a bidirectional recurrent deep neural network (“BRDNN”), a deep Q-network, or a combination of two or more thereof, but the present disclosure is not limited thereto.

Additionally or alternatively, the artificial intelligence model may include a software structure in addition to a hardware structure. At least two of the above processing units and processors may be integrally implemented with one component (e.g., a single chip), or each of the above processing units and processors may be implemented with an independent component (e.g., a plurality of chips).

The auxiliary processor 112 may include a controller 112-1. The controller 112-1 may include an interface conversion circuit and a timing control circuit. The controller 112-1 receives an image signal from the main processor 111 and outputs image data obtained by converting a data format of the image signal so as to be suitable for the specification of an interface with the display device DD. The controller 112-1 may output various kinds of control signals to drive the display device DD.

The auxiliary processor 112 may further include a data conversion circuit 112-2, a gamma correction circuit 112-3, a rendering circuit 112-4, etc. The data conversion circuit 112-2 may receive image data from the controller 112-1. The data conversion circuit 112-2 may compensate for the image data such that an image is displayed with a desired luminance depending on a characteristic of the electronic device ED or user settings or may convert the image data to reduce power consumption or to compensate for afterimages.

The gamma correction circuit 112-3 may convert the image data or the gamma reference voltage such that an image displayed on the electronic device ED has a desired gamma characteristic.

The rendering circuit 112-4 may receive the image data from the controller 112-1 and may render the image data in consideration of a pixel arrangement of the display panel DP applied to the electronic device ED.

At least one of the data conversion circuit 112-2, the gamma correction circuit 112-3, or the rendering circuit 112-4 may be integrated into any other component (e.g., the main processor 111 or the controller 112-1). At least one of the data conversion circuit 112-2, the gamma correction circuit 112-3, or the rendering circuit 112-4 may be integrated into the data driver DDV to be described below.

The memory 120 may store various data used by at least one component (e.g., the processor 110 or the sensor module 161) of the electronic device ED and input data or output data for commands related thereto. The memory 120 may include at least one of the volatile memory 121 or the nonvolatile memory 122.

The input module 130 may receive a command or data to be used by a component (e.g., the processor 110, the sensor module 161, or the sound output module 163) of the electronic device ED from the outside of the electronic device ED (e.g., the user or the external electronic device 102).

The input module 130 may include a first input module 131 to which a command or data is input from the user and a second input module 132 to which a command or data is input from the external electronic device 102. The first input module 131 may include a microphone, a mouse, a keyboard, a key (e.g., a button), or a pen (e.g., a passive pen or an active pen).

The second input module 132 may support a specified protocol capable of connecting to the external electronic device 102 by wire or wirelessly. According to an embodiment, the second input module 132 may include a high definition multimedia interface (“HDMI”), a universal serial bus (“USB”) interface, a secure digital (“SD”) card interface, or an audio interface. The second input module 132 may include a connector capable of being physically connected with the external electronic device 102, for example, an HDMI connector, a USB connector, an SD card connector, or an audio connector (e.g., a headphone connector).

The display device DD visually provides information to the user. As described with reference to FIG. 4, the display device DD may include the display panel DP, the scan driver SDV, and the data driver DDV. The display device DD may further include a window, a chassis, and a bracket for protecting the display panel DP.

The display panel DP may include a liquid crystal display panel, an organic light emitting display panel, or an inorganic light emitting display panel, and the type of the display panel DP is not particularly limited. The display panel DP may be of a rigid type or may be of a flexible type capable of being rolled or folded. The display device DD may further include a supporter that supports the display panel DP, a bracket, or a heat radiating member.

The display device DD may further include a voltage generation circuit. The voltage generation circuit may output various kinds of voltages for driving the display panel DP.

The power supply module 150 supplies power to the components of the electronic device ED. The power supply module 150 may include a battery that charges a power supply voltage. The battery may include a primary cell not recharged, a secondary cell rechargeable, or a fuel cell. The power supply module 150 may include a power management integrated circuit (“PMIC”). The PMIC supplies power optimized for the display device DD and each of the modules. The power supply module 150 may include a wireless power transmission/reception member electrically connected with the battery. The wireless power transmission/reception member may include a plurality of antenna radiators in the form of a coil.

The electronic device ED may further include the internal module 160 and the external module 170. The internal module 160 may include the sensor module 161, the antenna module 162, and the sound output module 163. The external module 170 may include the camera module 171, a light module 172, and the communication module 173.

The sensor module 161 may sense an input by the user's body or an input by a pen of the first input module 131 and may generate an electrical signal or a data value corresponding to the input. The sensor module 161 may include at least one of the fingerprint sensor 161-1, the input sensor 161-2, or a digitizer 161-3.

The fingerprint sensor 161-1 may generate a data value corresponding to the user's fingerprint. The fingerprint sensor 161-1 may include one of an optical fingerprint sensor or a capacitive fingerprint sensor.

The input sensor 161-2 may generate a data value corresponding to coordinate information of the input by the user's body or the input by the pen. The input sensor 161-2 generates a capacitance change due to the input as a data value. The input sensor 161-2 may sense the input by the passive pen or may exchange data with the active pen.

The input sensor 161-2 may measure a biometric signal such as blood pressure, moisture, or body fat. For example, when the user touches his/her body part to a sensor layer or a sensing panel and does not move during a given time period, the input sensor 161-2 may detect the biometric signal based on a change in an electric field caused by the body part and may output the information desired by the user to the display device DD.

The digitizer 161-3 may generate a data value corresponding to the coordinate information of the input by the pen. The digitizer 161-3 generates the amount of electromagnetic change by the input as a data value. The digitizer 161-3 may sense the input by the passive pen or may exchange data with the active pen.

At least one of the fingerprint sensor 161-1, the input sensor 161-2, or the digitizer 161-3 may be implemented with a sensor layer disposed on the display panel DP through a continuous process. The fingerprint sensor 161-1, the input sensor 161-2, and the digitizer 161-3 may be disposed above/on the display panel DP, and at least one of the fingerprint sensor 161-1, the input sensor 161-2, or the digitizer 161-3, for example, the digitizer 161-3 may be disposed below/under the display panel DP.

At least two of the fingerprint sensor 161-1, the input sensor 161-2, and the digitizer 161-3 may be integrally formed with one sensing panel through the same process. When they are integrally formed with one sensing panel, the sensing panel may be disposed between the display panel DP and the window disposed above/on the display panel DP. According to an embodiment, the sensing panel may be disposed on the window, and the location of the sensing panel is not specifically limited.

At least one of the fingerprint sensor 161-1, the input sensor 161-2, or the digitizer 161-3 may be embedded in the display panel DP. That is, at least one of the fingerprint sensor 161-1, the input sensor 161-2, or the digitizer 161-3 may be simultaneously formed through a process of forming elements (e.g., a light emitting element and transistors) included in the display panel DP.

In addition, the sensor module 161 may generate an electrical signal or a data value corresponding to an internal state or an external state of the electronic device ED. The sensor module 161 may further include, for example, a gesture sensor, a gyro sensor, a barometric pressure sensor, a magnetic sensor, an acceleration sensor, a grip sensor, a proximity sensor, a color sensor, an infrared (“IR”) sensor, a biometric sensor, a temperature sensor, a humidity sensor, or an illuminance sensor.

The antenna module 162 may include one or more antennas to transmit or receive the signal or power to or from an external source. According to an embodiment, through an antenna suitable for a communication method, the communication module 173 may transmit a signal to an external electronic device or may receive a signal from the external electronic device. An antenna pattern of the antenna module 162 may be integrated with one component (e.g., the display panel DP) of the display device DD or the input sensor 161-2.

The sound output module 163 that is a device for outputting a sound signal to the outside of the electronic device ED may include, for example, a speaker used for general purposes such as multimedia playback or recording playback and a receiver used exclusively for receiving calls. According to an embodiment, the receiver and the speaker may be either integrally or separately implemented. A sound output pattern of the sound output module 163 may be integrated with the display device DD.

The camera module 171 may photograph a still image and a moving image. According to an embodiment, the camera module 171 may include one or more lenses, an image sensor, or an image signal processor. The camera module 171 may further include an infrared camera capable of measuring the presence or absence of the user, the location of the user, and the line of sight of the user.

The light module 172 may provide light. The light module 172 may include a light emitting diode or a xenon lamp. The light module 172 may operate in conjunction with the camera module 171 or may operate independently.

The communication module 173 may establish a wired or wireless communication channel between the electronic device ED and the external electronic device 102 and may support communication execution through the established communication channel. The communication module 173 may include one of a wireless communication module, such as a cellular communication module, a short-range wireless communication module, or a global navigation satellite system (“GNSS”) communication module, and a wired communication module, such as a local area network (“LAN”) communication module or a power line communication module or may include all thereof.

The communication module 173 may communicate with the external electronic device 102 over a short-range communication network such as Bluetooth, Wi-Fi direct, or infrared data association (“IrDA”) or a long-range communication network such as a cellular network, an Internet, or a computer network (e.g., a LAN or WAN). Various kinds of communication modules 173 described above may be implemented with one chip or with separate chips, respectively.

The input module 130, the sensor module 161, the camera module 171, etc. may be used to control the operation of the display device DD in conjunction with the processor 110.

The processor 110 outputs commands or data to the display device DD, the sound output module 163, the camera module 171, or the light module 172 based on the input data received from the input module 130. For example, the processor 110 may generate the image data corresponding to the input data applied through the mouse or the active pen and may output the image data to the display device DD; alternatively, the processor 110 may generate command data corresponding to the input data and may output the command data to the camera module 171 or the light module 172.

When input data is not received from the input module 130 during a given time period, the processor 110 may switch an operating mode of the electronic device ED to a low-power mode or a sleep mode such that the power consumption of the electronic device ED is reduced.

The processor 110 outputs commands or data to the display device DD, the sound output module 163, the camera module 171, or the light module 172 based on the sensing data received from the sensor module 161. For example, the processor 110 may compare authentication data obtained through the fingerprint sensor 161-1 with authentication data stored in the memory 120 and may then execute an application depending on a comparison result.

The processor 110 may execute a command based on the sensing data sensed by the input sensor 161-2 or the digitizer 161-3 or may output image data corresponding to the sensing data to the display device DD. When the sensor module 161 includes a temperature sensor, the processor 110 may receive temperature data associated with the measured temperature from the sensor module 161 and may further perform luminance correction on the image data based on the temperature data.

The processor 110 may receive measurement data about the presence or absence of the user, the location of the user, and the line of sight of the user from the camera module 171. The processor 110 may further perform the luminance correction on the image data based on the measurement data. For example, the processor 110 that determines the presence or absence of the user through the input from the camera module 171 may output, to the display device DD, image data whose luminance is corrected through the data conversion circuit 112-2 or the gamma correction circuit 112-3.

Some of the above components may be connected with each other through a communication scheme between peripheral devices, for example, a bus, a general purpose input/output (“GPIO”), a serial peripheral interface (“SPI”), a mobile industry processor interface (“MIPI”), or a ultra path interconnect (“UPI”) link and may exchange signals (e.g., commands or data). The processor 110 may communicate with the display device DD through a given interface. For example, one of the communication methods described above may be used, and the present disclosure is not limited thereto.

The electronic device ED according to various embodiments of the present disclosure may be implemented as various types of devices. The electronic device ED may include, for example, at least one of a portable communication device (e.g., a smart phone), a computer device, a portable multimedia device, a portable medical device, a camera, a wearable device, or home appliances. The electronic device ED according to an embodiment of the present disclosure is not limited to the above devices.

According to the embodiments of the present disclosure, when the inorganic insulating layers are etched to form the first contact hole, the first electrode including titanium, which has a much lower etch rate than the inorganic insulating layers, may be used as a mask, and thus the first contact hole may be more precisely manufactured.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A display device comprising:
a first transistor;
an insulating layer disposed on the first transistor;
a first connecting electrode disposed on the insulating layer and connected to the first transistor through a contact hole defined in the insulating layer; and
a light emitting element including an anode disposed on the first connecting electrode and electrically connected to the first connecting electrode,
wherein the first connecting electrode includes:
a first electrode disposed on a portion of the insulating layer adjacent to the contact hole; and
a second electrode disposed on the first electrode and within the contact hole, and connected to the first transistor, and
wherein an upper surface of a portion of the first electrode adjacent to the contact hole has an inclined surface.

2. The display device of claim 1, wherein the first electrode is not disposed within the contact hole.

3. The display device of claim 1, wherein the first electrode and the second electrode include different materials from each other, and the first electrode includes titanium.

4. The display device of claim 1, wherein the first electrode includes:
a first portion adjacent to the contact hole and having an upper surface formed of the inclined surface; and
a second portion spaced further apart from the contact hole than the first portion and having a flat upper surface.

5. The display device of claim 1, further comprising:
a second transistor disposed in a layer between the first transistor and the light emitting element, connected to a first gate electrode of the first transistor and a data line, and configured to be switched by a write scan signal,
wherein the first connecting electrode is disposed in a same layer as a second gate electrode of the second transistor.

6. The display device of claim 5, wherein the first transistor includes a silicon semiconductor, and the second transistor includes an oxide semiconductor.

7. The display device of claim 5, wherein the first connecting electrode includes a same material as the second gate electrode.

8. The display device of claim 5, wherein the second gate electrode includes:
a first-first electrode; and
a second-first electrode disposed on the first-first electrode,
wherein the first-first electrode is disposed in the same layer as the first electrode of the first connecting electrode and includes a same material as the first electrode, and
wherein the second-first electrode is disposed in a same layer as the second electrode the first connecting electrode and includes the same material as the second electrode.

9. The display device of claim 5, wherein the first connecting electrode further includes:
a third electrode disposed on the second electrode; and
a fourth electrode disposed on the third electrode, and
wherein the first electrode, the second electrode, and the fourth electrode include a same material, and the third electrode includes a material different from the material of the first electrode, the second electrode, and the fourth electrode.

10. The display device of claim 9, wherein the second gate electrode includes:
a first-first electrode;
a second-first electrode disposed on the first-first electrode;
a third-first electrode disposed on the second-first electrode; and
a fourth-first electrode disposed on the third-first electrode,
wherein the first-first electrode is disposed in a same layer as the first electrode of the first connecting electrode and includes a same material as the first electrode,
wherein the second-first electrode is disposed in a same layer as the second electrode of the first connecting electrode and includes a same material as the second electrode,
wherein the third-first electrode is disposed in a same layer as the third electrode of the first connecting electrode and includes a same material as the third electrode, and
wherein the fourth-first electrode is disposed in a same layer as the fourth electrode of the first connecting electrode and includes a same material as the fourth electrode.

11. The display device of claim 1, further comprising:
a second connecting electrode disposed on the first connecting electrode and connected to the first connecting electrode; and
a third connecting electrode disposed on the second connecting electrode and connected to the second connecting electrode,
wherein the anode of the light emitting element is disposed on the third connecting electrode and connected to the third connecting electrode.

12. The display device of claim 1, wherein the insulating layer includes a plurality of inorganic insulating layers.

13. A method for manufacturing a display device, the method comprising:
providing a first transistor on a substrate;
providing an insulating layer on the first transistor;
providing a first electrode on the insulating layer;
removing a first portion of the first electrode overlapping a hole area of the insulating layer;
defining a contact hole in the insulating layer by removing the hole area using a remaining portion of the first electrode as a mask;
providing a second electrode on the first electrode and within the contact hole;
removing portions of the first electrode and the second electrode other than a first portion of the second electrode disposed within the contact hole and second portions of the first electrode and the second electrode disposed on a portion of the insulating layer adjacent to the contact hole;
providing a light emitting element on a first connecting electrode including the first portion of the second electrode and the second portions of the first electrode and the second electrode; and
electrically connecting the first connecting electrode to an anode of the light emitting element.

14. The method of claim 13, wherein an upper surface of a part of the second portion of the first electrode adjacent to the contact hole has an inclined surface.

15. The method of claim 13, further comprising:
providing a second transistor above the first transistor,
wherein the second transistor is connected to a first gate electrode of the first transistor and the anode of the light emitting element and configured to be switched by a write scan signal, and
wherein the first connecting electrode is disposed in a same layer as a second gate electrode of the second transistor.

16. The method of claim 15, wherein the first transistor includes a silicon semiconductor, and the second transistor includes an oxide semiconductor, and
wherein the first connecting electrode is disposed in a same layer as the second gate electrode and includes a same material as the second gate electrode.

17. The method of claim 15, wherein the second gate electrode includes:
a first-first electrode; and
a second-first electrode disposed on the first-first electrode,
wherein the first-first electrode is disposed in a same layer as the first electrode and includes a same material as the first electrode, and
wherein the second-first electrode is disposed in a same layer as the second electrode and includes a same material as the second electrode.

18. The method of claim 15, further comprising:
providing a third electrode on the second electrode;
providing a fourth electrode on the third electrode; and
removing portions of the third electrode and the fourth electrode other than first portions of the third electrode and the fourth electrode disposed within the contact hole and second portions of the third electrode and the fourth electrode disposed on the portion of the insulating layer adjacent to the contact hole,
wherein the first connecting electrode further includes the first and second portions of the third electrode and the fourth electrode.

19. The method of claim 18, wherein the second gate electrode of the second transistor includes:
a first-first electrode;
a second-first electrode disposed on the first-first electrode;
a third-first electrode disposed on the second-first electrode; and
a fourth-first electrode disposed on the third-first electrode,
wherein the first-first electrode is disposed in a same layer as the first electrode and includes a same material as the first electrode,
wherein the second-first electrode is disposed in a same layer as the second electrode and includes the same material as the second electrode,
wherein the third-first electrode is disposed in a same layer as the third electrode and includes a same material as the third electrode, and
wherein the fourth-first electrode is disposed in a same layer as the fourth electrode and includes a same material as the fourth electrode.

20. An electronic device comprising:
a display device configured to display an image; and
a power supply module supplying power to the display device,
wherein the display device includes:
a first transistor;
an insulating layer disposed on the first transistor;
a first connecting electrode disposed on the insulating layer and connected to the first transistor through a contact hole defined in the insulating layer; and
a light emitting element including an anode disposed on the first connecting electrode and electrically connected to the first connecting electrode,
wherein the first connecting electrode includes:
a first electrode disposed on a portion of the insulating layer adjacent to the contact hole; and
a second electrode disposed on the first electrode and within the contact hole, and connected to the first transistor, and
wherein an upper surface of a portion of the first electrode adjacent to the contact hole has an inclined surface.
